(19) United States
(12) Patent Application Publication
(10) Pub. No.: US 2025/0374746 A1
(43) Pub. Date: Dec. 4, 2025

(54) LIGHT-EMITTING ELEMENT, LIGHT-EMITTING DEVICE, AND METHOD FOR MANUFACTURING LIGHT-EMITTING ELEMENT

(71) Applicant: Sharp Display Technology Corporation, Kameyama City, Mie (JP)

(72) Inventors: Ryo KITAMURA, Sakai City, Osaka (JP); Yuma YAGUCHI, Sakai City, Osaka (JP)

(21) Appl. No.: 18/872,824

(22) PCT Filed: Jun. 9, 2022
(86) PCT No.: PCT/JP2022/023301

§ 371 Date: Dec. 8, 2024

(51) Int. Cl. H10K 50/115; H10K 102/00

(52) U.S. Cl. CPC H10K 50/115; H10K 2102/311

(57) ABSTRACT

A light-emitting element includes: an anode and a cathode; and at least one layer provided between the anode and the cathode, and containing a first material having a bandgap of 3.0 eV or more and a thermal conductivity of 200 W/mK or more.

### TECHNICAL FIELD

The present disclosure relates to a light-emitting element, a light-emitting device, and a method for manufacturing the light-emitting element.

### BACKGROUND ART

Quantum-dot light-emitting diodes (QLEDs) are also referred to as nano light-emitting diodes (LEDs). Such a light-emitting element has: a pair of electrodes including an anode and a cathode; and layers with low thermal conductivity, such as an organic layer and a nanoparticle layer, contained between the pair of electrodes. The light-emitting element is low in thermal diffusivity, and insufficient for dissipating heat. Hence, such a light-emitting element inevitably accumulates heat when emitting light at high luminance. The accumulation of heat leads to degradation of the light-emitting element.

Patent Document 1 discloses an organic electroluminescence (EL) device including: an anode; a light-emitting layer; and a cathode, all of which are stacked on top of another from toward a substrate. The cathode includes two layers; that is, a first cathode layer is a conventional cathode, and a second cathode layer is provided outside the first cathode and formed of either graphene or modified graphene. Patent Document 1 describes that graphene and modified graphene excel in heat dissipation properties, thereby successfully dissipating heat of the entire device. Furthermore, graphene and modified graphene have gas barrier properties. According to Patent Document 1, the organic EL device can be provided with the gas barrier properties.

### CITATION LIST

### Patent Literature

[Patent Document 1] Chinese Patent Application Publication No. 110504384

### SUMMARY

### Technical Problems

However, a light-emitting element referred to as a QLED includes, as a light-emitting layer, a nanoparticle layer referred to as a quantum dot layer containing quantum dots. The inventors of the present application have considered that, as to such a light-emitting element, currently, the quantum dot layer occupies most of the series resistance at the time of driving by injection electroluminescence, and that, in the driving, heat is generated mainly from the quantum dot layer. The quantum dot layer is low in thermal conductivity. Furthermore, the low thermal conductivity is also observed either: on an organic layer provided between the quantum dot layer and the anode, or between the quantum dot layer and the cathode; or on a nanoparticle layer other than the quantum dot layer.

Hence, even if such a light-emitting element has the cathode including two layers one of which is a conventional cathode and another one of which is a layer provided outside the conventional cathode and formed of either graphene or modified graphene, the configuration is not sufficient for further diffusing heat accumulated in the quantum dot layer.

In addition, instead of forming the cathode with two layers, a layer made of graphene or modified graphene could be provided between the cathode and the anode. Such a case would cause problems below. Hereinafter, for convenience of description, the term “graphene or modified graphene” is collectively referred to simply as “graphene”.

Graphene has metallic conductivity. Hence, if a layer containing graphene is present between the cathode and the anode, a current inevitably flows through the graphene, and leaks. That is, a current leakage path is inevitably formed.

Furthermore, graphene has no bandgap, and a work function of the graphene is present within a bandgap of quantum dots. Hence, if a layer containing graphene is present between the cathode and the anode, electric charges flow more into the graphene than into the quantum dots. As a result, the quantum dots fail to generate excitons, which causes non-light-emitting recombination. Moreover, the excitons of the quantum dots are separated into electrons and holes, which causes exciton quenching. As a result, emission of light is inhibited.

Moreover, graphene is not very chemically stable, which poses a disadvantage; that is, graphene is either oxidized or decomposed while, for example, the light-emitting element is driven, and cannot maintain thermal conductivity and the above-described barrier properties.

One aspect of the present disclosure is devised in view of the above problems, and sets out to provide a light-emitting element and a light-emitting device that diffuse more heat than ever before and demonstrate high reliability, without increasing non-light-emitting recombination or exciton quenching. The one aspect also sets out to provide a method for manufacturing the light-emitting element.

### Solution to Problems

In order to solve the above problems, a light-emitting element according to an aspect of the present disclosure includes: a first electrode and a second electrode; and at least one layer provided between the first electrode and the second electrode, and containing a first material having a bandgap of 3.0 eV or more and a thermal conductivity of 200 W/mK or more.

In order to solve the above problems, a light-emitting device according to an aspect of the present disclosure includes at least one light-emitting element according to an aspect of the present disclosure.

In order to solve the above problems, a method for manufacturing a light-emitting element according to an aspect of the present disclosure includes: a step of forming the first electrode; a step of forming the second electrode; and, between the step of forming the first electrode and the step of forming the second electrode, a step of forming a layer containing a first material having a bandgap of 3.0 eV or more and a thermal conductivity of 200 W/mk or more.

### Advantageous Effects of Disclosure

One aspect of the present disclosure can provide a light-emitting element and a light-emitting device that diffuse more heat than ever before and demonstrate high reliability, without increasing non-light-emitting recombination or exciton quenching. The one aspect can also provide a method for manufacturing the light-emitting element.

### BRIEF DESCRIPTION OF DRAWINGS

FIG. 1 is a cross-sectional view schematically illustrating an example of a light-emitting element according to a first embodiment.

FIG. 2 is a view schematically illustrating a crystal structure of a c-BN nanoparticle.

FIG. 3 is a view schematically illustrating a crystal structure of an h-BN nanoparticle.

FIG. 4 is a flowchart showing a method for manufacturing the light-emitting element illustrated in FIG. 1.

FIG. 5 is a diagram illustrating accumulation of Joule heat due to low thermal conductivity of each of the layers in a comparative light-emitting element in which a layer containing a first material is not provided between an anode and a cathode.

FIG. 6 is a graph illustrating a relationship between a heating temperature and a PLQY of a quantum-dot thin film.

FIG. 7 is a graph illustrating a relationship between a heating temperature and a PL emission lifetime of a quantum-dot thin film.

FIG. 8 is a graph illustrating a result of a reliability test for a comparative light-emitting element produced as an evaluation light-emitting element.

FIG. 9 is an optical microscope image of a quantum dot used in FIG. 8 and observed after element leakage has occurred because of influence of locally accumulated heat.

FIG. 10 is a diagram showing a problem of a comparative light-emitting element using graphene as a first material for comparison.

FIG. 11 is a view illustrating, together with an energy band of BN, energy bands of the layers of the comparative light-emitting element illustrated in FIG. 10.

FIG. 12 is a cross-sectional view schematically illustrating an example of a light-emitting element according to a second embodiment.

FIG. 13 is a cross-sectional view schematically illustrating an example of a method for forming a layer containing a first material and included in the light-emitting element according to the second embodiment.

FIG. 14 is a diagram showing a problem of moving impurities in the comparative light-emitting element without a layer, containing the first material, between an anode and a cathode.

FIG. 15 is a graph showing a result of measuring, by the AES, elements contained in a cathode to a quantum dot layer of a light-emitting element. In the light-emitting element, a layer containing the first material is not provided between the anode and the cathode.

FIG. 16 is a graph illustrating a relationship between a vapor deposition rate, a drive voltage, and a luminance when a light-emitting element is produced to have the same configuration as that of the light-emitting element used for the measurement in FIG. 15 while the vapor deposition rate of the cathode (Ag) is varied.

FIG. 17 is a graph illustrating a relationship between a vapor deposition rate, a drive voltage, and a current density of a drive current when a light-emitting element is produced to have the same configuration as that of the light-emitting element used for the measurement in FIG. 15 while the vapor deposition rate of Ag is varied.

FIG. 18 is a graph illustrating a relationship between a vapor deposition rate, a current density of a drive current and a luminance when a light-emitting element is produced to have the same configuration as that of the light-emitting element used for the measurement in FIG. 15 while the vapor deposition rate of Ag is varied.

FIG. 19 is a graph illustrating a relationship between a vapor deposition rate, a current density of a drive current, and an external quantum efficiency when a light-emitting element is produced to have the same configuration as that of the light-emitting element used for the measurement in FIG. 15 while the vapor deposition rate of Ag is varied.

FIG. 20 is an image showing the light-emitting element emitting light by electroluminescence when the light-emitting element is manufactured to have the same configuration as that of the light-emitting element used for the measurement in FIG. 15, while Ag has a vapor deposition rate of 0.2 Å/s.

FIG. 21 is an image showing the light-emitting element emitting light by electroluminescence when the light-emitting element is manufactured to have the same configuration as that of the light-emitting element used for the measurement in FIG. 15, with Ag having a vapor deposition rate of 0.4 Å/s.

FIG. 22 is a cross-sectional view schematically illustrating an example of a light-emitting element according to a third embodiment.

FIG. 23 is a cross-sectional view schematically illustrating an example of another light-emitting element according to the third embodiment.

FIG. 24 is a cross-sectional view schematically illustrating an exemplary configuration of a main feature of a light-emitting device according to a fourth embodiment.

### DESCRIPTION OF EMBODIMENTS

First, described below will be an outline of a light-emitting element according to an aspect of the present disclosure. Note that, hereinafter, the term “below” means that a constituent feature is formed in a previous process before a comparative layer, and the term “above” means that a constituent feature is formed in a successive process after a comparative layer. Furthermore, hereinafter, the statement “A to B” as to two numbers A and B means “A or more and B or less” unless otherwise specified.

### Outline of Light-Emitting Element According to One Aspect of Present Disclosure

A light-emitting element according to an aspect of the present disclosure includes: a first electrode; a second electrode; and at least one functional layer provided between the first electrode and the second electrode. Then, the at least one functional layer includes a layer containing a material (hereinafter referred to as a “first material”) having a bandgap (Eg) of 3.0 eV or more and a thermal conductivity of 200 W/mK or more. Note that, in the present disclosure, a material used for improving the thermal diffusivity (i.e., a heat diffusing material) in the present disclosure is referred to as a “first material”, and is distinguished from functional materials such as a light-emitting material and a charge transport material that are conventionally used for purposes other than thermal diffusion and originally contained in a functional layer between the first electrode and the second electrode.

The at least one functional layer may include either only one layer containing the first material or a plurality of layers containing the first material. Hence, the light-emitting element according to an aspect of the present disclosure includes at least one layer provided between the first electrode and the second electrode and containing the first material.

The light-emitting element includes at least one layer provided between the first electrode and the second electrode and containing the first material. Thanks to such a feature, the light-emitting element can diffuse more heat than ever before and demonstrate high reliability, without increasing non-light-emitting recombination or exciton quenching.

One of the first electrode or the second electrode is an anode, and another one is a cathode. The above light-emitting element may have a conventional structure in which the lower electrode serves as the anode and the upper electrode serves as the cathode. Alternatively, the light-emitting element may have an inverted structure in which the lower electrode serves as the cathode and the upper electrode serves as the anode.

Note that, in the present disclosure, the layers between the first electrode and the second electrode are referred to as functional layers. The functional layers include at least a light-emitting layer. Hereinafter, the “light-emitting layer” is referred to as an “EML”.

When the EML emits light, the light-emitting element can release the light from toward a light-transparent electrode. Hence, at least one of the anode or the cathode is a light-transparent electrode. These electrodes in a pair may be light-transparent electrodes. However, one of the electrodes is desirably what is referred to as a reflective electrode reflective to light. In such a case, the light-emitting element may be either a bottom-emission light-emitting element or a top-emission light-emitting element. Desirably, the light-emitting element is a bottom-emission light-emitting element.

The light-emitting element can be used suitably as a light source of a light-emitting device such as, for example, a display device or a lighting device. If the light-emitting element is a bottom-emission light-emitting element, the upper electrode to be used as a common electrode for the light-emitting device can be formed of a thick metal electrode that functions as a heat bath with a large heat capacity. Hence, the bottom-emission light-emitting element excels in heat dissipation properties because heat is diffused by the first material, thereby successfully reducing a further temperature rise.

The light-emitting element may be either a single layer including one EML alone as the functional layer, or a multilayer including a plurality of functional layers as the functional layer.

If the light-emitting element includes the EML alone as the functional layer, the EML contains the first material. Whereas, if the light-emitting element includes the EML and a functional layer other than the EML, the first material may be contained either in the EML alone or in the functional layer alone other than the EML. Furthermore, the first material may be contained in both the EML and the functional layer other than the EML.

Moreover, as can be seen, if the plurality of functional layers are provided between the first electrode and the second electrode, the first material may be contained either in some of the functional layers alone, or in all of the functional layers. If the first material is contained in some functional layers alone, the first material may be contained, for example, either in any one of the functional layers alone, or in any given two or more of the functional layers but not in all the functional layers.

Hence, the light-emitting element may include at least the EML between the first electrode and the second electrode, and at least the EML may contain the first material.

In addition, the light-emitting element may include, as a functional layer other than the EML, at least one charge transport layer between the first electrode and the second electrode. That is, the light-emitting element may include the EML between the first electrode and the second electrode, and may also include the charge transport layer at least one of between the first electrode and the EML or between the second electrode and the EML. Then, at least one of the charge transport layer (i.e., the charge transport layer provided at least one of between the first electrode and the EML or between the second electrode and the EML) or the EML may contain the first material.

If the light-emitting element includes the charge transport layer serving as a functional layer other than the EML, the light-emitting element may include, as the charge transport layer, either a hole transport layer alone or an electron transport layer alone. In addition, the light-emitting element may include, as the charge transport layer, both the hole transport layer and the electron transport layer. Hereinafter, the hole transport layer is referred to as an “HTL”, and the electron transport layer is referred to as an “ETL”.

According to an aspect of the present disclosure, if the light-emitting element includes an HTL, the first material may be contained in the HTL. The HTL is provided between the anode and the EML. Furthermore, if the light-emitting element includes an ETL, the first material may be contained in the ETL. The ETL is provided between the cathode and the EML. If the light-emitting element includes the HTL and the ETL, the first material may be contained either in the HTL alone, or in the ETL alone. Alternatively, the first material may be contained in both the HTL and the ETL.

Furthermore, the light-emitting element may include a charge injection layer serving as a functional layer other than the EML. The charge injection layer may be either a hole injection layer or an electron injection layer. Hereinafter, the hole injection layer is referred to as an “HIL”, and the electron injection layer is referred to as an “EIL”.

According to an aspect of the present disclosure, if the light-emitting element includes an HIL, the first material may be contained in the HIL. The HIL is provided between the anode and the HTL. Moreover, if the light-emitting element includes the EIL, the first material may be contained in the EIL. The EIL is provided between the cathode and the ETL. If the light-emitting element includes the HIL and the EIL, the first material may be contained either in the HTL alone, or in the EIL alone. Alternatively, the first material may be contained in both the HIL and the EIL.

As can be seen, if the plurality of functional layers are provided between the first electrode and the second electrode, the first material may be contained in any one of the plurality of functional layers alone. Hence, if the light-emitting element includes the charge injection layer as described above, the first material may be contained either in the charge injection layer alone, or in the plurality of functional layers including the charge injection layer.

In addition, the functional layer other than the EML may be a first material layer made of the first material alone. Hence, in order to diffuse more heat, the functional layer between the first electrode and the second electrode may include at least one first material layer formed of the first material.

Many light-emitting elements currently being developed include, for example, an HIL, an HTL, and an ETL serving as functional layers other than an EML. Thus, hereinafter, as a specific embodiment, exemplified below in detail with reference to the drawings will be a case where a light-emitting element according to an aspect of the present disclosure includes an HIL, an HTL, an EML, and an ETL, all of which serve as functional layers.

Note that the light-emitting element according to an aspect of the present disclosure shall not be limited to such an example. The functional layers other than the EML may be functional layers other than those described above as an example. Such functional layers may include, for example, an electron injection layer, an electron-blocking layer, and a hole-blocking layer.

Note that, hereinafter, for convenience in description, like reference signs designate members having identical functions throughout the embodiments. These members will not be elaborated upon repeatedly. Furthermore, in a second and subsequent embodiments to be described later, differences from the previously described embodiments will be described. As a matter of course, unless otherwise described, the second and subsequent embodiments can be modified in the same manner as the previously described embodiments.

### First Embodiment

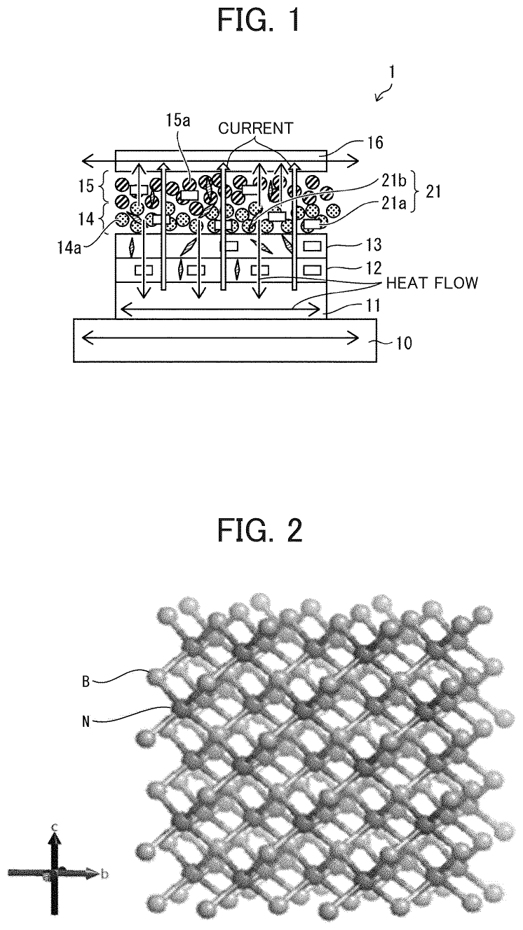

FIG. 1 is a cross-sectional view schematically illustrating an example of a light-emitting element 1 according to this embodiment.

FIG. 1 shows, as an example, a case where the light-emitting element 1 is a bottom-emission light-emitting element having a conventional structure in which an anode 11 serves as a lower electrode and a cathode 16 serves as an upper electrode. However, as described above, the light-emitting element according to an aspect of the present disclosure shall not be limited to such an example. The light-emitting element may be a top-emission light-emitting element having an inverted structure in which the cathode 16 serves as a lower electrode and the anode 11 serves as an upper electrode.

The light-emitting element 1 illustrated in FIG. 1 includes: the anode 11; an HIL 12; an HTL 13; an EML 14; an ETL 15; and the cathode 16, all of which are arranged in the stated order frow below.

The anode 11 is formed on a substrate 10. The substrate 10 functions as a support body that supports all of the layers including the anode 11 to the cathode 16. Hence, the light-emitting element 1 may include the substrate 10 serving as a support body.

The substrate 10 may be, for example, a rigid inorganic substrate such as a glass substrate. Alternatively, the substrate 10 may be a flexible substrate mainly formed of such a resin as polyimide. Note that the substrate 10 may be provided with, for example, a not-shown thin-film transistor (TFT) and a capacitive element.

The anode 11 is an electrode that receives a voltage to supply holes to the EML 14. The cathode 16 is an electrode that receives a voltage to supply electrons to the EML 14. Each of the anode 11 and the cathode 16 contains a conductive material and connects to a not-shown power supply, so that a voltage is applied between the anode 11 and the cathode 16.

The light-emitting element 1 according to this embodiment is, for example, a bottom-emission light-emitting element as described above, and uses a light-transparent electrode to serve as the anode 11 and a reflective electrode to serve as the cathode 16.

The light-transparent electrode is formed of a conductive light-transparent material such as, for example, indium tin oxide (ITO). Whereas, the reflective electrode is formed of a conductive light-reflective material including either a metal such as, for example, aluminum (Al) and silver (Ag), or an alloy containing such metals. Note that the light-reflective electrode may be a multilayer stack including a layer made of a light-transparent material and a layer made of a light-reflective material.

The HIL 12 is a charge injection layer containing a hole-transporting material and having a hole injection function to enhance efficiency in injecting the holes from the anode 11 into the HTL 13. Examples of the hole-transporting material include a composite (PEDOT: PSS) containing poly (3,4-ethylenedioxythiophene) (PEDOT) and polystyrene sulphonate (PSS).

The HTL 13 is a charge transport layer containing a hole-transporting material and having a hole transport function to enhance efficiency in transporting the holes to the EML 14. Examples of the hole-transporting material include poly[N,N′-bis(4-butylphenyl)-N,N′-bis(phenyl)-benzidine] (p-TPD) and poly[(9,9-dioctylfluorenyl-2,7-diyl)-co-(4,4′-(N-4-sec-butylphenyl))diphenylamine)] (TFB).

The EML 14 contains a light-emitting material, and emits light by recombination of the holes transported from the anode 11 and the electrons transported from the cathode 16. The light-emitting element 1 is a self-luminous element referred to as a QLED (or a nano LED). The EML 14 is a QD layer containing, as a light-emitting material, quantum dots (hereinafter referred to as “QDs”) 14a in a nano size depending on a color of the light.

The QDs 14a are dots each having a maximum width of 100 nm or less. The QD is also referred to as a semiconductor nanoparticle because a typical composition of the QD is derived from a semiconductor material. Moreover, the QD is also referred to as a nanocrystal because the QD has a specific crystal structure.

Each of the QDs 14a may have any given shape as long as the maximum width of the QD 14a is within the above range. The shape of the QD 14a shall not be limited to a three-dimensional spherical shape (a circular cross-section). For example, the QD 14a may have a polygonal cross-section, a bar-like three dimensional shape, a branch-like three dimensional shape, or a three dimensional shape having asperities on the surface. Alternatively, the QD 14a may have a combination of those shapes.

Each of the QDs 14a may be a core QD. Alternatively, each of the QDs 14a may be either a core-shell QD containing a core and a shell, or a core-multishell QD containing a core and shells. If the QD 14a contains a shell, the QD 14a may have a core in the center, and the shell may be provided to a surface of the core. The shell desirably covers the entire core; however, the shell does not have to completely cover the core. Furthermore, the QD 14a may be a binary-core QD, a tertiary-core QD, or a quaternary-core QD. Note that the QDs 14a may contain doped nanoparticles, or may have a composition-gradient structure.

The core may be formed of, for example, Si, Ge, CdSe, CdS, CdTe, InP, GaP, InN, ZnSe, ZnS, ZnTe, CdSeTe, GalnP, or ZnSeTe. The shell may be formed of, for example, CdS, ZnS, CdSSe, CdTeSe, CdSTe, ZnSSe, ZnSTe, ZnTeSe, or AIP.

An emission wavelength of the QD 14a can be varied in various manners depending on, for example, the size and the composition of the particle. The QD 14a emits visible light. A particle size and a composition of the QD 14a are appropriately adjusted so that the emission wavelength of the QD 14a can be controlled.

The EML14 may contain not-shown ligands. The ligands may be coordinated to the surface (or near the surface) of the QDs 14a. The ligands contained in the EML 14 can keep the QDs 14a from agglomerating together. Hence, target optical properties are easily expressed.

Note that, in present disclosure, the “ligands” are a compound having a coordinating function. If the EML 14 contains both the QDs 14a and the ligands, at least some of the ligands are assumed to be coordinated to the QDs 14a. In the present disclosure, the term “ligands” collectively refers not only to molecules or ions coordinated to the surface of the QDs 14a but also to molecules or ions which can be coordinated but are not coordinated.

The ligands shall not be limited to particular ligands, and may be any given various known ligands. The ligands may be organic ligands such as, for example, oleylamine (OA), dodecanethiol (DDT), trioctylphosphine (TOP), or dodecylamine (DAM). Furthermore, the ligands may be inorganic ligands such as halogen ligands (e.g., Cl⁻, Br⁻, or F⁻).

The ETL 15 is a charge transport layer containing an electron-transporting material and having an electron transporting function to enhance efficiency in transporting the electrons to the EML 14. The electron-transporting material is formed of nanoparticles 15a capable of transporting electrons.

Note that, in the present disclosure, the term “nanoparticles” refers to dots (particles) formed of particles having a maximum width of less than 1000 nm. A nanoparticle may have any given shape as long as the maximum width of the nanoparticle is within the above range. The shape of the nanoparticle shall not be limited to a spherical shape (a circular cross-section). For example, the nanoparticle may have a polygonal cross-section, a bar-like three dimensional shape, a branch-like three dimensional shape, or a three dimensional shape having asperities on the surface. Alternatively, the nanoparticle may have a combination of those shapes.

Examples of such nanoparticles 15a include nanoparticles of ZnO and MgZnO. Of these nanoparticles, ZnO nanoparticles (hereinafter, referred to as “ZnO-NPs”) are typically used.

FIG. 1 exemplifies a case where, in the light-emitting element 1, all the functional layers provided between the anode 11 and the cathode 16 contain a first material 21 having an Eg of 3.0 eV or more and a thermal conductivity of 200 W/mK or more. Hence, in the example shown in FIG. 1, each of the HIL12, the HTL13, the EML14, and the ETL 15 includes the first material 21.

According to this embodiment, the light-emitting element 1 includes at least one layer containing the first material 21 and provided between the anode 11 and the cathode 16. As described above, thanks to such a feature, the light-emitting element 1 can diffuse more heat than ever before and demonstrate high reliability, without increasing non-light-emitting recombination or exciton quenching. Then, as illustrated in FIG. 1, all the functional layers between the anode 11 and the cathode 16 contain the first material 21. Thanks to such a feature, the light-emitting element 1 can diffuse more heat and demonstrate higher reliability.

If the Eg is less than 3.0 eV or the thermal conductivity is less than 100W/mK, the light-emitting element 1 cannot sufficiently achieve the advantageous effects described above. In particular, if the Eg is less than 3.0 eV, the light-emitting element 1 might suffer non-light-emitting recombination and exciton quenching.

The thermal conductivity can be measured with, for example, the Thermowave Analyzer TA. Note that the thermal conductivity of the first material 21 is a value unique to the material. If the thermal conductivity cannot be measured with the above measurement apparatus, values to be used may be those typically disclosed in public, such as specifications in a catalog.

Higher thermal conductivity represents higher thermal diffusivity. Hence, a higher upper limit of the thermal conductivity is more desirable, and shall not be limited to a particular level. However, the thermal conductivity of diamond, which is typically claimed to be high, is 1000 to 2000 W/mK. Furthermore, a recent study shows that the thermal conductivity of a carbon nanotube, which is claimed to be higher than the thermal conductivity of diamond, is reportedly 3000 W/mK. Hence, at present, the upper limit of the thermal conductivity is 3000 W/mK. Thus, the thermal conductivity of the first material 21 is 3000 W/mK or less at present, and is typically claimed to be 2000 W/mK or less. Note that, as described above, a higher upper limit of the thermal conductivity is more desirable. Hence, if the first material 21 has a thermal conductivity exceeding 3000 W/mk, such a first material 21 may definitely be used.

Furthermore, the Eg is measured with the spectrophotometer “U-3900” (model) manufactured by Hitachi High-Tech Science Corporation. The Eg varies depending on such factors as the production conditions and the particle size of the nanoparticles. For example, if the material and the crystal system are the same, the Eg is larger as the particle size of the nanoparticles is smaller. If the Eg cannot be measured with the above measurement apparatus, values to be used may be those typically disclosed in public, such as specifications in a catalog.

The first material 21 may have a value of a valance band maximum (VBM) larger (deeper) than a value of a VBM of the QDs 14a, and may have a value of a conduction band minimum (CBM) smaller (shallower) than a value of the CBM of the QDs 14a. However, in order to sufficiently reduce the non-light-emitting recombination and the exciton quenching, the first material desirably has an Eg of 3.0 eV or more as described above. Furthermore, the first material 21 desirably has: a value of the VBM larger than a value of a valence band maximum (VBM) of the ETL 15 such as ZnO-NPs; and a value of the CBM smaller (shallower) than a value of a conduction band minimum (CBM) of the HTL 13. Such a feature can prevent the electrons and the holes from leaking to the counter electrodes, and enhance efficiency in injecting the charges into the QDs 14a. Note that the value of the VBM here represents an absolute value of the difference in energy level of the electrons between the vacuum level and the VBM. Furthermore, the value of the CBM here represents an absolute value of the difference in energy level of the electrons between the vacuum level and the CBM.

If the EML 14 contains the first material 21, a carrier confirmation effect is higher as the Eg is larger. Accordingly, light can be emitted more efficiently. However, in both photoluminescence (PL) and electroluminescence (PL), carriers that should collect in a QD layer such as the EML 14 inevitably escape (i.e., the carriers diffuse) to layers found in the surroundings of the QD layer and having a smaller Eg. Note that the surroundings of the QD layer shall not be limited to layers adjacent to the QD layer. For example, even a multilayer structure including a QD layer/a thin HTL/a layer with a small Eg/an HTL/an HIL could cause the carriers to diffuse. Hence, even in the case of a functional layer other than the QD layer, if the Eg of the functional layer is large, the carriers do not diffuse into the functional layer, and the light can be emitted more efficiently. Thus, even if the first material 21 is contained in any of the functional layers, a larger Eg is more desirable for the first material 21.

Hence, a higher upper limit of the Eg is more desirable, and shall not be limited to a particular level. Note that if the Eg is large, the first material 21 becomes an insulator. The first material 21 having an Eg of 3.0 eV or larger is an insulator. A typically known insulator having a large Eg is, for example, SiO₂ . SiO₂ has an Eg of 8.9 eV. Hence, the upper limit of the Eg can be deemed to be approximately 9 eV at present, and, preferably 10 eV. However, the upper limit of the thermal conductivity is 3000 W/mk. Thus, the thermal conductivity of the first material 21 is claimed to be 3000 W/mk or less at present, and, typically, 2000 W/mk or less. Note that, as described above, a higher upper limit of the Eg is more desirable. Hence, if the first material 21 has an Eg exceeding 10 eV, such a first material 21 may definitely be used.

As described above, if the EML 14 contains the first material 21, a content of the first material 21 in the EML 14 is desirably 25% or higher and 80% or lower in a cross-sectional area ratio with respect to the EML 14, and, more desirably, 45% or higher and 80% or lower. Such a feature can increase the thermal conductivity of the EML 14 serving as a QD layer to improve thermal diffusivity, and reduce local concentration of heat. Hence, the feature can reduce degradation of QDs 14a, and, eventually, degradation of the light-emitting element 1.

Furthermore, if the HTL 13 contains the first material 21, a content of the first material 21 in the HTL 13 is desirably 25% or higher and 80% or lower in a cross-sectional area ratio with respect to the HTL 13, and, more desirably, 45% or higher and 80% or lower. Likewise, if the ETL 15 contains the first material 21, a content of the first material 21 in the ETL 15 is desirably 25% or higher and 80% or lower in a cross-sectional area ratio with respect to the ETL 15, and, more desirably, 45% or higher and 80% or lower. Both of such features can increase the thermal conductivity of the charge transport layer adjacent to the QD layer to improve thermal diffusivity, and reduce local concentration of heat. Hence, the features can reduce degradation of QDs 14a, and, eventually, degradation of the light-emitting element 1.

As described above, the first material 21 may be contained in any of the functional layers between the anode 11 and the cathode 16, and may be contained in, for example, the HIL12 serving as the charge injection layer. If the HIL 12 contains the first material 21, a content of the first material 21 in the HIL 12 is desirably 25% or higher and 80% or lower in a cross-sectional area ratio with respect to the HIL 12, and, more desirably, 45% or higher and 80% or lower. Such features can increase the thermal conductivity of the HIL 12 provided between the EML 14 and the anode 11 to improve thermal diffusivity, and reduce local concentration of heat. Hence, the features can reduce degradation of QDs 14a, and, eventually, degradation of the light-emitting element 1.

As can be seen, if each of the functional layers between the anode 11 and the cathode 16 contains the first material 21, a content of the first material 21 in each of the functional layers is desirably 25% or higher and 80% or lower in a cross-sectional area ratio with respect to each functional layer, and, more desirably, 45% or higher and 80% or lower.

As can be seen, the content of the first material 21 is set to 25% or higher and 80% or lower in a cross-sectional area ratio. Such a feature can increase the thermal conductivity of the functional layers containing the first material 21 to improve thermal diffusivity, and reduce local concentration of heat. As a result, the feature can reduce degradation of QDs 14a, and, eventually, degradation of the light-emitting element 1. Furthermore, the content of the first material 21 is set to 45% or higher and 80% or lower in the cross-sectional area ratio. Such a feature can significantly improve the thermal diffusivity. Note that the above advantageous effects will be specifically described in detail later.

Whereas, if the first material 21 is mixed at a cross-sectional area ratio higher than 80%, the electrical resistance of all the layers including the first material 21 increases, leading to an increase in resistance. Furthermore, as described above, if the functional layers are those, formed of the first material alone, other than the first material layer, and have a function, other than the thermal diffusion function, such as, for example, a charge transport function, the amount of a functional material such as the charge transport material originally contained in the functional layers might be excessively small so that the functional layers could not sufficiently exhibit the original function.

The cross-sectional area ratio of the first material 21 can be obtained by Expression (1) below:

$$( A cross - sectional area of the entire first material 21 in a layer containing the first material 21 / a cross - sectional area of the entire layer containing the first material 21 ) \times 100 \% . \qquad ( 1 )$$

In obtaining the cross-sectional area ratio of the first material 21, the cross-section of the layer containing the first material 21 is checked, using an image obtained with an electron microscope. Then, the rate can be determined from a ratio of an area where the first material 21 is found in the cross-section to an area where the base material is found in the cross-section.

In this case, the cross-sectional area ratio of the first material 21 can be obtained with, for example, a transmission electron microscope (TEM), by calculating an area rate of the first material 21 to the focused layer containing the first material 21 in the image obtained with the TEM and showing the cross-section of the layer magnified at a 200-nm thickness.

Furthermore, the cross-sectional area ratio of the first material 21 can be determined also from a volume rate of the first material 21 to the layer containing the first material 21. For example, if the volume rate is 50%, the area rate obtained in cutting in a sufficiently large cross-section is, as a matter of course, also 50% in terms of probability.

Hence, the volume rate of the first material 21 to the layer containing the first material 21 may be obtained by Expression (2) below, as the cross-sectional area ratio is obtained:

$$( A cross - sectional area of the entire first material 21 in a layer containing the first material 21 / a cross - sectional area of the entire layer containing the first material 21 ) \times 100 \% . \qquad ( 2 )$$

Furthermore, the volumes are directly calculated by a method using a tiltable TEM. In the method, for example, a volume rate of the first material 21 to the focused layer within a region of the layer whose thickness is magnified at a 200-nm length by a 100-nm thickness is calculated from a hologram image formed of TEM images taken from multiple angles.

In this case, too, the volume rate of the first material 21 to the layer containing the first material 21 may be obtained by Expression (2) described above, as the cross-sectional area ratio is obtained:

The first material 21 may be any given material that satisfies the above conditions. Preferable examples of the first material 21 include boron nitride (BN). Among insulators and semiconductors, BN is one of the substances having very high thermal conductivity. In addition, BN is highly stable. BN is chemically so stable not to be decomposed even when heated at, for example, 900° C. in an oxidizing environment. Hence, for example, a certain amount of BN is mixed together as the first material 21. Such a feature can significantly improve thermal conductivity and keep a current leakage path from forming.

BN has several crystalline structures. As the first material 21, c-BN (cubic boron nitride) and h-BN (hexagonal boron nitride) are particularly preferable among BNs.

The c-BN nanoparticles have a crystal structure illustrated in FIG. 2. The c-BN nanoparticles, similar in structure to diamond, have a thermal conductivity of 740 W/mK and an Eg of 6.4 eV.

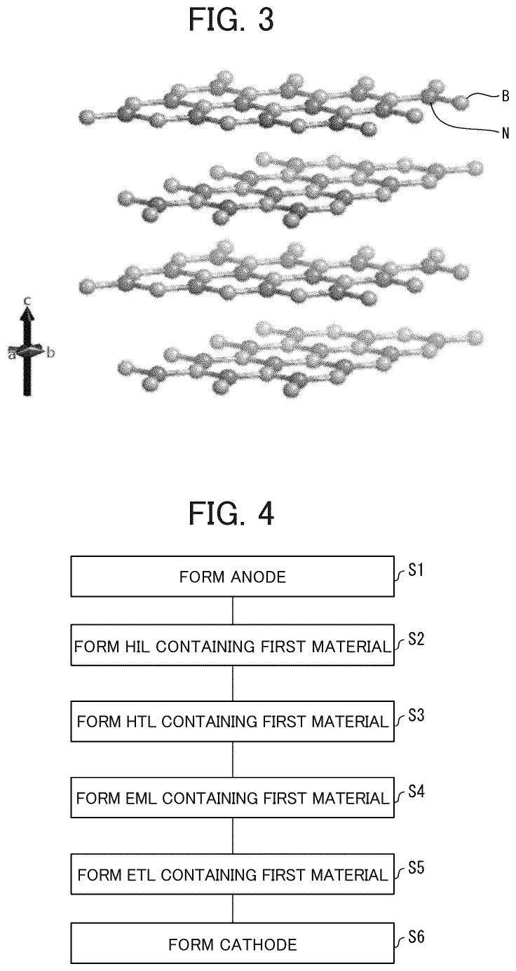

Furthermore, h-BN has a crystal structure illustrated in FIG. 3. A bulk of h-BN has a structure in which h-BN is in monoatomic layers loosely bonding on the c-axis. The bulk of h-BN can be separated into single layers or several atomic layers of h-BN when the crystals of the h-BN are peeled off with, for example, a tape. Hereinafter, the h-BN separated into single layers or several atomic layers is referred to as an “h-BN nanosheet”.

While the c-BN nanoparticles are non-anisotropic, the h-BN nanosheet (e.g., a single-layer h-BN) is anisotropic, and the thermal conductivity of the h-BN nanosheet is significantly different between the c-axis direction and the a-axis direction. When h-BN nanosheets are stacked together in a direction perpendicular to a film surface (a film thickness direction), a single-layer h-BN has a thermal conductivity (k⊥) of approximately 30 W/mk. When a single-layer h-BN lies in a film-surface direction in parallel with main surfaces of the h-BN nanosheets, the single-layer h-BN has a thermal conductivity (k_{//}) of 600 W/mk. Furthermore, an h-BN nanosheet has an Eg of 6.0 eV.

Furthermore, as illustrated in FIG. 3, the h-BN nanosheet has a mesh structure in which B atoms and N atoms are densely arranged. The h-BN nanosheet has a high barrier property against impurities in the direction perpendicular to the film surface, and can prevent, for example, oxygen molecules, water molecules, and other impurities from permeating in the direction perpendicular to the film surface. Hence, the first material 21 preferably contains the h-BN nanosheets.

Note that, the first material 21 shall not be limited to BN. Any given first material is similarly applicable as long as the first material has an Eg of 3.0eV or more and a thermal conductivity of 200 W/mK or more. As described above, the first material 21 may be either anisotropic or non-anisotropic. The thermal conductivity does not have to be 200 W/mK or more in all the directions, and may be 200 W/mK or more in any one of the direction.

The Eg of the QDs 14a is larger as the peak emission wavelength is shorter. If the light-emitting element 1 is used as a light source of a full-color display device including red pixels emitting a red light, green pixels emitting green a light, and blue pixels emitting a blue light, for example, the blue pixels having a shortest peak emission wavelength are formed of QDs 14a that emit a blue light. The QDs 14a that emit a blue light have an Eg of approximately 2.7 eV. Hence, if the Eg is 3.0 eV or more, emission of light by excitons is not inhibited in the light-emitting material, regardless of the kind of the QDs 14a. If the thermal conductivity is 200 W/mK or more, heat can be sufficiently conducted even if the QDs 14a are mixed together with a low first material.

FIG. 1 exemplifies a case where each functional layer includes, as the first material 21, c-BN nanoparticles denoted by a numeral reference “21a” in FIG. 1 and h-BN nanosheets denoted by a numeral reference “21b” in FIG. 1. Hereinafter, the c-BN nanoparticles are referred to as “c-BN nanoparticles 21a”. Furthermore, the h-BN nanosheets are referred to as “h-BN nanosheets 21b”.

As illustrated in FIG. 1, Expression 3 below suggested by Eucken is applicable in calculating a thermal conductivity of a mixture of two materials having different thermal conductivities:

$$K = {K}_{f} ( 1 + 2 φ A / 1 - φ A ) \qquad ( 3 )$$

$$wherein A = ( 1 - {K}_{f} / {K}_{s} ) ( 2 {K}_{f} / {K}_{s} + 1 ) .$$

If spherical particles having a thermal conductivity Kₛ are uniformly dispersed in a continuous medium having a thermal conductivity K_{f} at a volume fraction φ, and the dispersed particles are sufficiently spaced apart from one another, the thermal conductivity K of the mixture can be obtained by Expression (3) above.

Note that FIG. 1 exemplifies a case where, as described above, each functional layer includes both the c-BN nanoparticles 21a and the h-BN nanosheets 21b. However, each functional layer may contain either the c-BN nanoparticles 21a or the h-BN nanosheets 21b alone.

Furthermore, as described above, if the first material 21 is the h-BN nanosheets 21b, an average thickness of the h-BN nanosheets is desirably 2 nm or less per unit area of a cross-section, of a layer containing the first material 21, in a thickness direction. Note that each of the h-BN nanosheets 21b, including six atomic layers, is approximately 2 nm in thickness. Hence, the h-BN nanosheet 21b contains desirably six atomic layers or fewer.

The h-BN nanosheets 21b are an insulator. The average thickness of the h-BN nanosheets 21b is set to allow a sufficient tunneling current to flow, thereby successfully reducing an increase in voltage because of the mixed insulator.

Note that the average thickness of the h-BN nanosheets 21b can be obtained with, for example, a TEM by calculating an average thickness of the h-BN nanosheets 21b contained in a focused layer in the image obtained with the TEM and showing the cross-section of the layer magnified at a 200-nm thickness.

### Manufacturing Method

A method for manufacturing a light-emitting element according to an aspect of the present disclosure includes: a step of forming a first electrode; a step of forming a second electrode; and a step of forming a layer containing the first material 21 between the step of forming the first electrode and the step of forming the second electrode.

Described below will be a method for manufacturing a light-emitting element according to an aspect of the present disclosure, with reference to a method for manufacturing the light-emitting element 1 illustrated in FIG. 1 as an example.

FIG. 4 is a flowchart showing a method for manufacturing the light-emitting element 1 illustrated in FIG. 1.

As described above, the light-emitting element 1 illustrated in FIG. 1 has a conventional structure in which the anode 11 serves as a lower electrode and the cathode 16 serves as an upper electrode. Each of the HIL 12, the HTL 13, the EML 14, and the ETL 15 contains the first material 21.

Hence, in the method for manufacturing the light-emitting element 1 illustrated in FIG. 1, as shown in FIG. 4, first, the anode 11 is formed on the substrate 10 (Step S1).

Next, the plurality of functional layers are formed above the anode 11. Specifically, as shown in FIG. 4, first, the HIL 12 containing the first material 21 is formed to serve as a functional layer (Step S2). Next, the HTL13 containing the first material 21 is formed (Step S3). Next, the EML 14 containing the first material 21 is formed (Step S4). Next, the ETL 15 containing the first material 21 is formed (Step S5). Note that the light-emitting element 1 illustrated in FIG. 1 exemplifies a case where, as described above, each of the HIL 12, the HTL 13, the EML 14, and the ETL 15 contains the first material 21. However, as described above, the light-emitting element 1 according to an aspect of the present disclosure may include at least one layer containing the first material 21 between the anode 11 and the cathode 16. Hence, at the step of forming a functional layer, at least one layer containing the first material 21 may be formed.

After that, the cathode 16 is formed (Step S6). This is how the light-emitting element 1 illustrated in FIG. 1 is produced. The above method makes it possible to significantly improve thermal conductivity of the layers in which the first material 21 is mixed, and to reduce degradation of the layers because of heat accumulation (specifically, degradation of a material forming each of the layers); in particular, degradation of the QDs 14a in the EML14. Such features can improve reliability.

The methods for forming the anode 11 and the cathode 16 are the same as those conventionally applied. The anode 11 and the cathode 16 are formed by, for example, vapor deposition, sputtering, or inkjet printing.

Each of the functional layers included in the light-emitting element 1 can be formed of a coat. Each functional layer can be formed by, for example, spin coating, vacuum evaporation, inkjet printing, or imprinting.

The HIL 12 can be formed of a dispersion liquid containing: an HIL material such as, for example, PEDOT:PSS; and the first material 21. The dispersion liquid is applied to the anode 11 and then baked so that the solvent is vaporized. Thus, the HIL 12 can be formed. The HTL 13 can be formed of a dispersion liquid containing: an HTL material such as, for example, TFB; and the first material 21. The dispersion liquid is applied to the HIL 12 and then baked so that the solvent is vaporized. Thus, the HTL 13 can be formed. The EML 14 can be formed of a dispersion liquid containing: the QDs 14a; and the first material 21. The dispersion liquid is applied to the HTL 13 and then baked so that the solvent is vaporized. Thus, the EML 14 can be formed. The ETL 15 can be formed of a dispersion liquid containing: the nanoparticles 15a such as, for example, ZnO-NPs to be used as an ETL material; and the first material 21. The dispersion liquid is applied to the EML 14 and then baked so that the solvent is vaporized. Thus, the ETL 15 can be formed. Note that the dispersion liquid to be used for forming the EML 14 may contain ligands as described before. Furthermore, the dispersion liquid to be used for forming the ETL 15 may contain ligands, in order to improve dispersibility of the nanoparticles 15a. Moreover, here, in order to adjust the dispersibility of the first material 21 in the solvent, the ligands may be contained in the surface of the first material 21.

The first materials 21 contained in the respective HIL 12, HTL13, EML14, and ETL15 may be the same or different. Furthermore, the ligands contained in the respective EML14 and ETL 15 may also be the same or different.

The solvent contained in each of the dispersion liquid to be applied to form the functional layers may be a polar solvent. Here, the polar solvent is a solvent having a relative permittivity of 10 or more. Examples of the solvent include ethanol, methanol, and water.

As described above, the first material 21 is suitably either the c-BN nanoparticles 21a or the h-BN nanosheets 21b. These c-BN nanoparticles 21a and h-BN nanosheets 21b can also be dispersed in the polar solvent. Hence, a dispersion liquid is prepared to contain a material of each of functional layers and the BN at any given ratio, and the dispersion liquid is applied to form the functional layer. As a result, each functional layer can be formed to contain the BN mixed at any given ratio.

Note that, in the example illustrated in FIG. 1, the c-axis directions of the crystals of the h-BN nanosheets 21b are oriented in random directions. However, depending on the film formation conditions, the c-axis directions of the crystals of the h-BN nanosheets 21b can be oriented in a specific direction by a certain amount with a certain probability. Specifically, for example, when the dispersion liquid is applied, an external force is applied in, for example, a specific direction. Such a force can intentionally orient the h-BN nanosheets 21b in the specific direction. Note that, unlike the h-BN nanosheets 21b, the c-BN nanoparticles 21a are not anisotropic, and do not need to be oriented particularly in the same direction.

In a state where the material of each of the functional layers is mixed together with BN such as the c-BN nanoparticles 21a and the h-BN nanosheets 21b, the c-axis directions of the crystals of the h-BN nanosheets 21b are oriented in random directions. Hence, in each of the dispersion liquids, the h-BN nanosheets 21b are oriented in random direction. Thus, for example, when each dispersion liquid forms a film, the film is formed under a condition in which the dispersion liquid flows less. As a result, the dispersion liquid forms a functional layer in which the h-BN nanosheets 21b are oriented at random.

### Advantageous Effects

Described next will be advantageous effects of the above light-emitting element 1.

As described before, a light-emitting element referred to as a QLED includes a QD layer serving as an EML. The inventors of the present application have considered that, as to most of the structures currently adopted to QLEDs, the QD layer occupies most of the resistance, and that, in the driving, heat is generated mainly from the quantum dot layer.

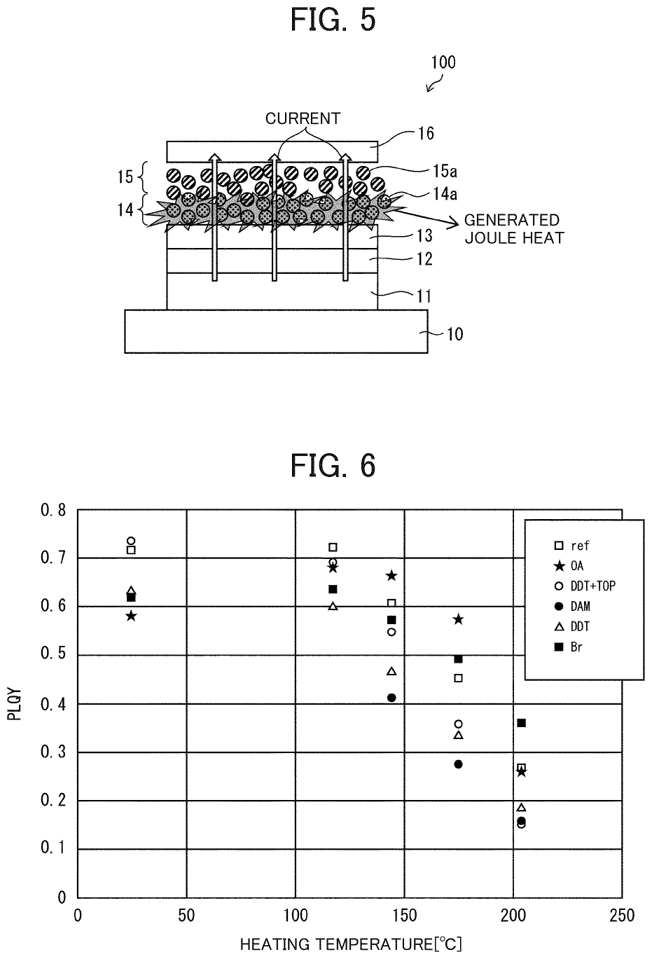

FIG. 5 is a diagram illustrating accumulation of Joule heat due to low thermal conductivity of each of the layers in a comparative light-emitting element 100 in which a layer containing the first material 21 is not provided between the anode 11 and the cathode 16.

FIG. 5 illustrates an exemplary case where the light-emitting element 100 includes: the anode 11; the HIL 12; the HTL 13; the EML 14; the ETL 15; and the cathode 16, all of which are provided above the substrate 10 in the stated order from below. The comparative light-emitting element 100 is the same in configuration as the light-emitting element 1 illustrated in FIG. 1 except that none of the functional layers between the anode 11 and the cathode 16 contains the first material 21.

The QDs 14a have a thermal conductivity of typically less than 1 W/m·K (e.g., 0.3 W/m·K or less). Furthermore, the HTL 13 and the ETL15, which are respectively provided below and above the EML14; namely, a QD layer, are also typically formed of materials having a thermal conductivity of significantly less than 20 W/m·K.

For example, as described above, ZnO-NPs are typically used for the ETL15. However, the crystalline grains of the nanoparticles are finer than those of the bulk, and phonon scattering occurs at the interface. Moreover, compared with the crystalline grains in the bulk, materials themselves of the nanoparticles are not sufficiently in contact with one another and the nanoparticles are spaced apart from one another. Hence, heat is not readily transferred through the nanoparticles. Thus, a bulk of ZnO has a thermal conductivity of 20 W/m·K; whereas, the ZnO-NP layer is deemed to have a thermal conductivity significantly lower than the thermal conductivity of the bulk of ZnO.

In addition, the HTL 13 is often formed of an organic material. As described before, the HTL 13 is formed of, for example, either p-TPD or TFB. Hence, the thermal conductivity of the HTL13 is deemed to be less than 0.3 W/m·K, which is equivalent to the thermal conductivities of, for example, epoxy resins and acrylic resins.

Likewise, the HIL 12 is also often formed of an organic material. As described before, the HIL 12 is formed of, for example, PEDOT: PSS. Hence, the thermal conductivity of the HIL 12 is also deemed to be less than 0.3 W/m·K.

Thus, the QD layer sandwiched between these functional layers is likely to accumulate Joule heat when a current is injected as illustrated in FIG. 5, and in the element configuration at present, the heat locally generated in the QD layer cannot be efficiently released out of the QD layer. As a result, the QD layer is likely to degrade quickly when, for example, emitting light at high luminance.

However, as described above, for example, the bottom-emission light-emitting element has an upper layer provided above the ETL 15 and formed of a metal film of 100 nm in thickness. ITO has a thermal conductivity of 10 W/m·K; whereas, Al and Ag respectively have thermal conductivities of 237 W/m·K and 420 W/m·K. As can be seen, the metal film having such a high thermal conductivity and a great thickness sufficiently functions as a heat bath with a large heat capacity as described above.

Hence, for example, the first material 21 such as BN is mixed into the ETL 15. Such a feature can improve the thermal conductivity of the ETL 15, increase the thermal diffusivity between the QD layer and the cathode 16, and release the heat from the QD layer.

For example, if the ETL 15 is formed of ZnO-NPs having a thermal conductivity of 20 W/mk, and c-BN nanoparticles having a thermal conductivity of 740 W/mk are mixed into the ETL 15 at the cross-sectional area ratio of 25%, the thermal conductivity of the ETL 15 containing the c-BN nanoparticles doubles to 41 W/mK according to Expression (3) described before. Furthermore, if the c-BN nanoparticles are mixed at the cross-sectional area ratio of 45% into the ETL 15 formed of ZnO-NPs, the thermal conductivity of the ETL 15 containing the c-BN approximately triples to 62.6 W/mK according to Expression (3) described before. Hence, in this case, assuming that the thermal conductivities and the heat capacities of the cathode 16 and the ETL15 containing the c-BN nanoparticles are constant around a driving temperature, the first material 21 can triple the performance of diffusing heat to the cathode 16 serving as a heat bath. As a result, in driving with a high current, the temperature rise of the EML 14 can be reduced to approximately one third.

Moreover, assuming that an amount of the degradation linearly increases with respect to a temperature difference, the reliability triples if the thermal conductivity triples. Note that one of the main reasons why the QDs are degraded is desorption of ligands because of heating. However, according to the Arrhenius law, the desorption of ligands is deemed accelerated exponentially with respect to a temperature rise. Hence, in practice, further improvement in reliability can be expected in a high temperature range.

Note that exemplified here is a case where the c-BN nanoparticles serving as the first material 21 are mixed into the ETL 15. Alternatively, the first material 21 other than the c-BN nanoparticles can be used to achieve the same advantageous effect of improving the thermal diffusivity by the first material 21. Furthermore, the same is true to a case where the first material 21 is mixed into the QD layer.

In a bottom-emission light-emitting element, if the anode serving as a lower electrode is formed of ITO, the lower electrode formed of conductive ITO and the substrate 10 are found below the QD layer, even though the lower electrode and the substrate 10 are far behind the metal film in thermal conductivity. Hence, also below the QD layer, if the functional layers between the EML 14 and the anode 11 improve in thermal conductivity, and, as illustrated in FIG, 1, if such layers as the QD layer, the HTL 13, and the HIL 12 improve in thermal diffusivity, the heat can be released sufficiently from the QD layer. Furthermore, here, the ITO film may be thinned to, for example, 50 nm or less, in order to enhance the thermal diffusivity.

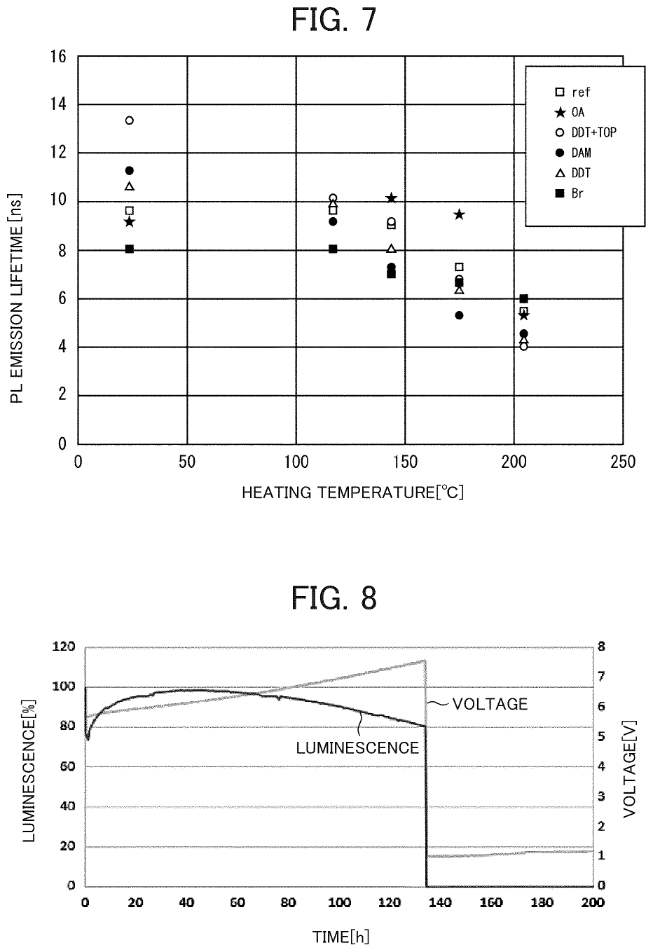

Here, described below will be a relationship between a heating temperature and degradation of the QDs 14a with reference to FIGS. 6 and 7.

As to FIGS. 6 and 7, a light-emitting element, formed of a single film of the QDs 14a prepared on a glass plate and sealed, is heated at a certain temperature, and, after that, cooled to a room temperature. FIGS. 6 and 7 show optical properties measured for the light-emitting element while various kinds of ligands are used.

As shown in FIGS. 6 and 7, the ligands used were the above-described OA, DDT, TOP, DAM, Br, and Per. Note that, in FIGS. 6 and 7, an explanatory legend “DDT+TOP” indicates that, as ligands, DDT and TOP were used in combination at a ratio of 1:1.

FIG. 6 shows a result of measuring a PLQY as an optical property of the light-emitting element, and a relationship between a PLQY and a heating temperature of a quantum-dot thin film; that is, a single film formed of the QDs 14a. FIG. 7 shows a result of measuring a PL emission lifetime as an optical property of a quantum-dot thin film; that is, a single film formed of the QDs 14a, and a relationship between a PL emission lifetime and a heating temperature of a single film formed of the QDs 14a. Note that, in the present disclosure, the term “PL emission lifetime” indicates a “time period until PL emission intensity becomes 1/e of the initial intensity”. If a defect occurs, the lifetime is shortened because non-light-emitting transition occurs. The “PL emission lifetime” is theoretically proportional to the light emission efficiency when measured on the same QDs.

The PLQY was measured using an absolute PL quantum yield measurement device “C9920-02” (model) manufactured by Hamamatsu Photonics K.K. The PL emission lifetime was measured using a compact fluorescence lifetime measurement device “Quantaurus-Tau (registered trademark)” manufactured by Hamamatsu Photonics K.K.

As illustrated in FIGS. 6 and 7, the QDs 14a do not degrade linearly. Degradation of the QDs 14a progresses exponentially as the heating temperature rises with reference to room temperature.

Furthermore, FIG. 8 is a graph illustrating a result of a reliability test for a comparative light-emitting element produced as an evaluation light-emitting element.

The evaluation light-emitting element was produced by the method below. First, on a glass substrate, an ITO film was formed as an anode to have a thickness of 30 nm. Next, a dispersion liquid was prepared of ethanol and nickel oxide (NiO) dispersed in the ethanol. On the ITO film, the dispersion liquid was applied and baked for one hour so that the solvent was vaporized. Thus, an NiO layer having a thickness of 43 nm was formed as an HTL. After that, 0.9 mg/ml of polymethylmethacrylate (PMMA) was mixed together with acetone. The mixture was applied to the NiO layer to form a PMMA layer. Next, a dispersion liquid containing CdSe as QDs was prepared. The dispersion liquid was applied to the PMMA layer and baked so that the solvent was vaporized. Thus, a QD layer having a thickness of 44 nm was formed to emit a green light. Next, a dispersion liquid containing ZnO-NPs having a diameter of 12 nm was prepared. The dispersion liquid was applied to the QD layer and baked so that the solvent was vaporized. Thus, a ZnO-NP layer having a thickness of 50 nm was formed as an ETL. Next, on the ZnO-NP layer, Al having a thickness of 100 nm was formed as a cathode.

In the reliability test, 11.03 mA/cm² of measurement current was supplied to the evaluation light-emitting element, and the initial luminance (1000 cd/m²) of the light-emitting element was determined as 100%. A relationship was measured between a time (h) for which the measurement current was supplied, a voltage, and a luminance (%) with respect to the initial luminance. For the measurement in the reliability test, an OLED life evaluation device “EAS-10G (model)” manufactured by System Engineering Co., Ltd. was used.

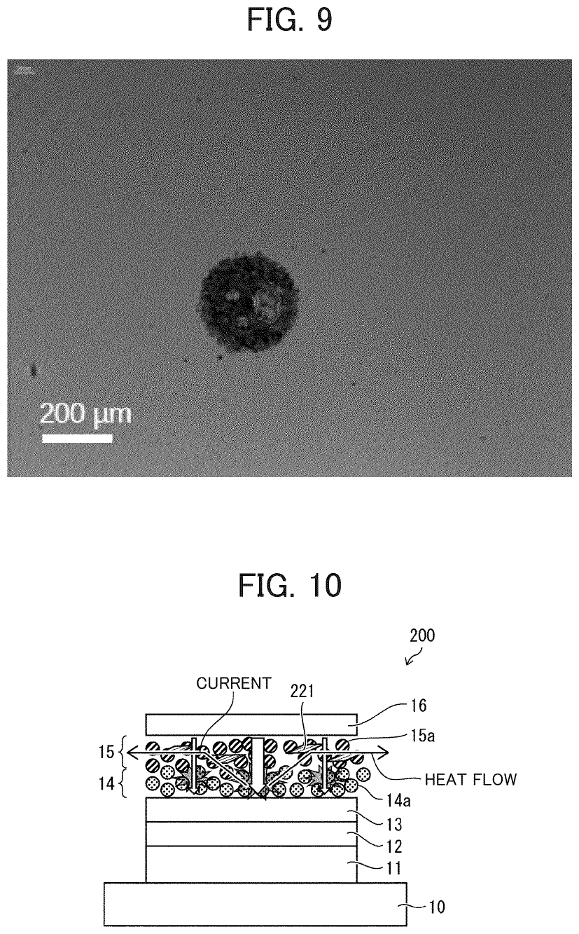

FIG. 9 is an optical microscope image of a QD of the QLED element in FIG. 8 after the reliability test. The QD is observed when heat is locally accumulated such that the element is partially deformed and element leakage occurs.

Typically, a QD layer in a light-emitting element has a thickness of 20 to approximately 40 nm, and the QDs themselves have a particle size (diameter) of approximately 10 to 15 nm. At a QD layer forming step, when the dispersion liquid containing QDs is applied, the QDs would be hardly arranged completely and densely in a certain number of layers, and the QDs would be partially thin for one layer, for example. This means that, if the QD layer is 30 nm in thickness and the QDs are 15 nm in diameter, a portion of the QD layer thinner for one layer than another portion is half as thick as the other region of the QD layer. Hence, the QD layer of the light-emitting element has not a few portions where a current readily flows locally when viewed in nanoscale. In addition, the QD layer is deemed to occupy most of the series resistance in the light-emitting element. Thus, a current flows readily in a portion where the QD layer is thin (i.e., where the ETL is thick instead).

As can be seen, if the QD layer has a thin portion (e.g., a pinhole), a current preferentially flows during driving in the thin portion of the QD layer because the thin portion exhibits low resistance. As a result, Joule heat is generated more than another portion.

For example, if a large amount of organic ligands are coordinated to the surface of QDs, the thermal conductivity of the QDs is close to the thermal conductivity of an organic substance, and is deemed to be, for example, 0.3 W/m·K or less as described above. Hence, the QD layer does not conduct heat sufficiently in a film surface direction, and the heat is likely to be accumulated in the thin portion of the QD layer. In particular, the pinhole portion exhibits low resistance. That is why Joule heat is generated significantly, and heat is locally generated and accumulated.

Thus, for example, if degradation locally progresses in the QD layer of the portion where the pinhole is generated, the QD layer is either deformed or altered, and thus the leakage current rises. As shown in FIG. 8, the light emission characteristics rapidly deteriorate. Furthermore, as shown in FIG. 9, the QDs are rapidly degraded.

The leakage current rises and eventually grows to a large leakage path, and as a result, most of the current flowing through the light-emitting element passes through the current leakage path, and the light-emitting element might not emit light.

The degradation of QDs because of temperature is non-linear with respect to a temperature rise. Hence, concentration of the heat at, for example, the pinhole portion is reduced so that improvement in reliability is observed also of the light-emitting element as a whole.

According to this embodiment, as described above, the first material 21 is mixed into the functional layers between the anode 11 and the cathode 16 to improve thermal diffusivity between the anode 11 and the cathode 16. Such a feature can solve the problems described above.

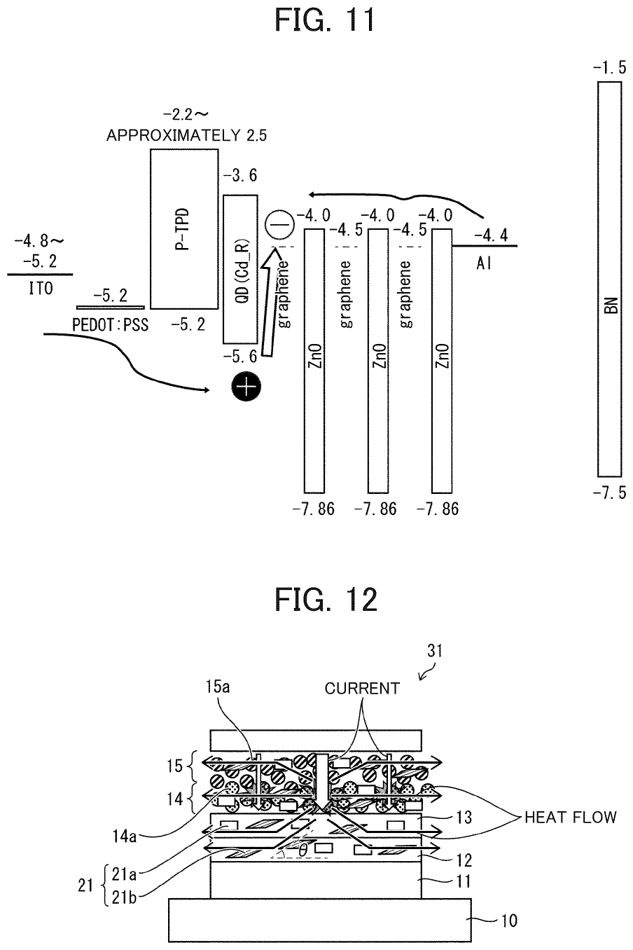

Furthermore, FIG. 10 is a diagram showing a problem of a comparative light-emitting element 200 using graphene as a first material for comparison. FIG. 11 is a view illustrating, together with an energy band of BN, energy bands of the layers of the comparative light-emitting element 200 illustrated in FIG. 10.

FIG. 10 illustrates an exemplary case where the light-emitting element 200 includes: the anode 11; the HIL 12; the HTL 13; the EML 14; the ETL 15; and the cathode 16, all of which are provided above the substrate 10 in the stated order from below. Moreover, the comparative light-emitting element 200 exemplifies a case where graphene is mixed into the ETL 15.

Similar to h-BN, graphene is also one of materials having high thermal conductivity. Furthermore, graphene has barrier properties such as hydrophobicity, ultraviolet resistance, and gas barrier properties. When mixed into the ETL 15, graphene is expected to improve thermal conductivity and exhibit barrier properties.

However, as described before, graphene has metallic conductivity. As illustrated in FIG. 10, if graphene denoted by a numeral reference “221” is mixed into, for example, the ETL 15, a current inevitably flows through the graphene, and leaks. Furthermore, graphene has no Eg, and a work function of the graphene is present within the Eg of the QDs 14a. Hence, as described before, graphene causes non-light-emitting recombination and exciton quenching. Moreover, graphene is not very chemically stable. Thus, graphene has disadvantages; that is, graphene is either oxidized or decomposed while the light-emitting element 200 is driven, and cannot maintain neither thermal conductivity nor the above-described barrier properties. That is why graphene is not suitable for exhibiting the advantageous effects according to one aspect of the present disclosure.

Whereas, the first material 21 has an Eg of 3.0 eV or more. As illustrated in FIG. 11, the Eg of the first material 21 is larger than the Eg of the QDs 14a. Hence, the first material 21 does not cause either non-light-emitting recombination or exciton quenching. Furthermore, as illustrated in FIG. 11, BN has: a value of the VBM as deep as a value of the VBM of the ETL 15 such as ZnO-NPs; and a value of the CBM smaller (shallower) than a value of the CBM of the HTL 13.

Moreover, BN such as the c-BN nanoparticles 21a and the h-BN nanosheets 21b is an insulator, and does not form a current leakage path. In addition, as described before, BN is significantly stable.

Thus, thanks to this embodiment, the light-emitting element 1 can diffuse more heat than ever before and demonstrate high reliability, without increasing non-light-emitting recombination or exciton quenching.

Furthermore, this embodiment reduces degradation of the QDs 14a emitting light at high luminance, thereby successfully reducing a decrease in light emission efficiency at high luminance. Moreover, the reduction in degradation of the QDs 14a can increase a photoluminescence (PL) emission lifetime, make light emitted at a high luminance, and achieve a higher photoluminescence quantum yield (PLQY).

In addition, as described before, the h-BN nanosheets 21b have a barrier effect. Such a feature makes it possible to block the layers from air contained in a process system, oxygen in the solvent, and oxygen slightly remaining in the light-emitting element 1. Furthermore, the h-BN nanosheets 21b keep such substances as, for example, impurities from diffusing. Such a feature can prevent the impurities from reacting with materials of the layers, and further improves reliability.

As described before, FIG. 1 exemplifies a case where the c-axis directions of the crystals of the h-BN nanosheets 21b are oriented in random directions. The h-BN nanosheets 21b oriented in random directions include h-BN nanosheets in which the c-axis directions of the crystals are oriented in a film thickness direction. Hence, when functional layers contain the h-BN nanosheets 21b in which the c-axis directions of the crystals are oriented in the film thickness direction, such a feature makes it possible to improve, as arrows representing heat flows show in FIG. 1, thermal conductivity, in the film thickness direction, of the layers containing the h-BN nanosheets 21b, thereby significantly improving thermal diffusivity in the film thickness direction.

Note that the h-BN nanosheets 21b oriented in random directions include h-BN nanosheets 21b in which the c-axis directions of the crystals are oriented in a film surface direction. Hence, when the functional layers contain the h-BN nanosheets 21b in which the c-axis directions of the crystals are oriented in the film surface direction, such a feature makes it possible to improve thermal conductivity, in the film surface direction, of the layers containing the h-BN nanosheets 21b, thereby significantly improving thermal diffusivity in the film surface direction. Furthermore, when the functional layers contain the h-BN nanosheets 21b in which the c-axis directions of the crystals are oriented in the film surface direction, such a feature can significantly improve barrier functions.

In any case, as described above, this embodiment can reduce deterioration of the layers because of heat accumulation (specifically, degradation of a material forming each of the layers); in particular, degradation of the QDs 14a in the EML14. Such a feature can provide the light-emitting element 1 with high reliability.

### Second Embodiment

FIG. 12 is a cross-sectional view schematically illustrating an example of a light-emitting element 31 according to this embodiment.

As described before, when a dispersion liquid containing the h-BN nanosheets 21b is applied, an external force is applied in, for example, a specific direction. Such a force can intentionally orient the c-axis directions of the crystals of the h-BN nanosheets 21b in a specific direction by a certain amount with a certain probability, depending on the film formation conditions.

In the light-emitting element 31 illustrated in FIG. 12, as to most of the h-BN nanosheets 21b, the c-axis directions of the crystals are oriented in a film surface direction of the functional layers containing the h-BN nanosheets 21b. Otherwise, the light-emitting element 31 illustrated in FIG. 12 is the same as the light-emitting element 1 illustrated in FIG. 1.

As described before, assume a case where, for example, the QD layer has a thin portion (e.g., a pinhole). If thermal conductivity of the QD layer is not sufficient in the film surface direction, a current preferentially flows during driving in the thin portion of the QD layer. As a result, heat is readily accumulated. Hence, when the thermal conductivity of the light-emitting element is improved in the film surface direction, such a feature can also reduce degradation of QDs 14a and the light-emitting element.

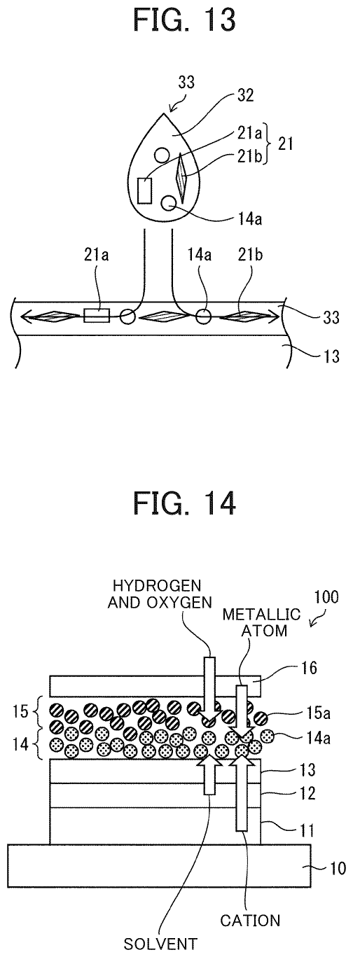

FIG. 13 is a cross-sectional view schematically illustrating an example of a method for forming a layer containing the first material 21 and included in the light-emitting element 31 according to this embodiment. Note that FIG. 13 shows a QD layer (i.e., the EML 14) as an example of the layer containing the first material 21, and partially illustrates a step of forming the QD layer.

The configuration illustrated in FIG. 12 is relatively easy to achieve in a solution process. In this embodiment, the h-BN nanosheets 21b are oriented in the film surface direction at a step of forming the layer containing the first material 21. Hence, as illustrated in FIG. 13, a dispersion liquid 33 containing the first material 21 is directed to flow in a direction parallel with the film surface direction of the HTL13 (an underlayer) below the layer containing the first material 21.

As described before, the c-BN nanoparticles 21a and h-BN nanosheets 21b can be dispersed in a polar solvent. The dispersion liquid 33 contains a solvent 32, and the solvent 32 may be the polar solvent.

Hence, at the step of forming the layer containing the first material 21, first, materials (the QDs 14a in the example of FIG. 13) of the layers, the first material 21, and the solvent 32 are mixed together at any given ratio. Thus, the dispersion liquid 33 is prepared to contain the materials of the layers, the first material 21, and the solvent 32. Here, when prepared, the dispersion liquid 33 is adjusted in, for example, viscosity. Hence, when delivered in droplets, the dispersion liquid 33 flows in parallel with the film surface direction of the lower layer. Thus, when the dispersion liquid 33 is delivered in droplets and falls, the falling droplets of the dispersion liquid 33 receive an external force. Because of the external force, the dispersion liquid 33 flows and spreads in parallel with the film surface direction of the lower layer. Because of a behavior of the h-BN nanosheets 21b observed when the dispersion liquid 33 falls, and of the flow of the h-BN nanosheets 21b caused by the flow of the dispersion liquid 33, most of the h-BN nanosheets 21b in the dispersion liquid 33 are oriented in parallel with the film surface direction of the lower layer. Note that the film surface direction of the lower layer can be also referred to either as a direction in parallel with a substrate surface or as a direction in parallel with an electrode surface. Thus, according to this embodiment, the h-BN nanosheets 21b can be oriented in a direction of a surface of a coating film formed of the applied dispersion liquid 33.

Here, as illustrated in FIG. 12, 0 is an angle formed between each of the h-BN nanosheets 21b and a plane in parallel with a film surface of a layer containing the h-BN nanosheets. When the dispersion liquid 33 containing the first material 21 is directed, by the external force generated when the dispersion liquid 33 is delivered in droplets, to flow in the film surface direction of the lower layer, an average value of the angle θ of a cross-section, in the thickness direction, of the layer containing the h-BN nanosheet 21b is smaller than 45 degrees. Note that the layer containing the h-BN nanosheet 21b may contain a plurality of the h-BN nanosheets 21b where θ=0 holds. Note that, in measuring the average value of the angle θ, the h-BN nanosheets 21b found at 100-nm intervals in a target layer may be measured when the cross-section is observed in the thickness direction, and then arithmetically averaged. Furthermore, as to the statement “an angle formed between each of the h-BN nanosheets 21b and a plane in parallel with a film surface of a layer containing the h-BN nanosheets”, if, in observation of the cross-section, a line intersection of the cross-section and a plane in parallel with the film surface of the layer is a line A and an line intersection of the cross-section and the h-BN nanosheet 21b is a line B, the angle may be one formed between the line A and the line B. Note that the average value of the angle θ of the cross-section, of the layer containing the h-BN nanosheet 21b, in the thickness direction is preferably 30 degrees or less, and more preferably, 15 degrees or less.

As described before, the h-BN nanosheets 21b have a high barrier property in the direction perpendicular to the film surface. The high barrier property can prevent, for example, oxygen molecules, water molecules, and other impurities from permeating in the direction perpendicular to the film surface. Hence, when the h-BN nanosheets 21b are oriented in, or close to, the film surface direction of the layer containing the h-BN nanosheets 21b, such a feature can prevent impurities from spreading in a stacking direction of the functional layers; that is, in the direction perpendicular to the film surface.

Note that when the h-BN nanosheets 21b are oriented in the film surface direction of each of the functional layers, the h-BN nanosheets may preferably have a size of 50 nm×50 nm or more, and, more preferably, a size of 100 nm×100 nm or more, in an intra-film direction of the h-BN nanosheets.

Thus, the h-BN nanosheets 21b have a sufficient size (i.e., a sufficient area) in the intra-film direction. Such a feature can keep impurities from spreading more efficiently.

Note that when the h-BN nanosheets have a size of 50 nm×50 nm or more in the intra-film direction, it means that each of the h-BN nanosheets has a wide surface region including a square of 50 nm×50 nm within the surface of the sheet. If one side of the square is less than 50 nm, the h-BN nanosheet is deemed not to have a size of 50 nm×50 nm or more even though the h-BN nanosheet has an area equivalent to 50nm×50nm. Likewise, when the h-BN nanosheets 21b have a size of 100 nm×100 nm or more in the intra-film direction, it means that the each of the h-BN nanosheets has a wide surface region including a square of 100 nm×100 nm within the surface of the sheet.

The h-BN nanosheets 21b have a size of 50 nm×50 nm or more, and, more preferably, a size of 100 nm×100 nm or more, in the intra-film direction. Thanks to such a feature, a large area can be covered with the h-BN nanosheets 21b connected together to serve a single barrier layer. As a result, a high barrier effect can be exhibited.

Note that the size of the h-BN nanosheets 21b can be observed by the following method. For example, a tiltable TEM is used for observation of: a TEM image obtained with a tilt function; and a size and a 3D arrangement of the h-BN nanosheets found in a volume of a total thickness of all the layers of the light-emitting element 31×a cutout thickness 100 nm×a length 200 nm in the film surface direction. Thus, a maximum size of the h-BN nanosheets can be observed. Note that, as seen in the observation of the volume rate described before, a hologram image may be prepared for observation.

Note that, also in this embodiment, because of the same reason in the first embodiment, the h-BN nanosheets desirably have an average thickness of desirably 2 nm or less (six atomic layers or fewer) per unit area of a cross-section, of a layer containing the first material 21, in a thickness direction.

Furthermore, also in this embodiment, because of the same reason in the first embodiment, a content of the first material 21 in the layers containing the first material 21 is desirably 25% or higher and 80% or lower in a cross-sectional area ratio with respect to each of the layers, and, more desirably, 45% or higher and 80% or lower.

The first embodiment exemplifies a case where the c-BN nanoparticles 21a are used as the first material 21, and specifically describes a relationship between a cross-sectional area ratio and an advantageous effect of improvement in thermal conductivity. However, even when the h-BN nanosheets 21b are used as the first material 21, the same advantageous effect can be obtained in the film surface direction. For example, where ZnO-NPs have a thermal conductivity of 20 W/mk, if the h-BN nanosheets 21b are mixed into a ZnO-NP layer at the cross-sectional area ratio of, for example, 25%, the thermal conductivity in the film surface direction can be approximately doubled according to Expression (3). Furthermore, if the h-BN nanosheets 21b are mixed into the ZnO-NP layer at the cross-sectional area ratio of, for example, 45%, the thermal conductivity in the film surface direction can be approximately tripled according to Expression (3).

Note that FIG. 12 also exemplifies a case where each functional layer includes both the c-BN nanoparticles 21a and the h-BN nanosheets 21b. Alternatively, each functional layer may contain the h-BN nanosheets alone. Moreover, also in this embodiment, the first material 21 may be mixed into at least one of the functional layers between the anode 11 and the cathode 16, and at least one layer containing the first material 21 may be included between the anode 11 and the cathode 16.

Thanks to this embodiment, as described above, the layers into which the h-BN is mixed exhibit significant improvement in thermal conductivity and thermal diffusivity. Such a feature can reduce degradation caused by locally accumulated heat. Furthermore, the Eg is the same as described in the first embodiment. Thanks to this embodiment, the light-emitting element 31 can diffuse more heat than ever before and demonstrate high reliability, without increasing non-light-emitting recombination or exciton quenching.

Moreover, as described before, each of the h-BN nanosheets 21b has a mesh structure in which B atoms and N atoms are densely arranged. Such a structure can prevent oxygen molecules, water molecules, and other impurities from permeating in the direction perpendicular to the film surface. In addition, the h-BN nanosheets 21b are provided between the anode 11 and the cathode 16. Hence, according to this embodiment, during a production process as well as driving, the light-emitting element 31 can keep impurities from reaching the QD layer and another functional layer.

Note that the h-BN is mixed into, in particular, a layer having many voids and formed of nanoparticles, thereby successfully reducing migration of the impurities in the light-emitting element 31. Such a feature can reduce impurity-related degradation, and further improve reliability. Details thereof will be described in more detail.

FIG. 14 is a diagram illustrating a problem of moving impurities in the comparative light-emitting element 100 without a layer, containing the first material 21, between the anode 11 and the cathode 16, as described before.

As to a light-emitting element referred to as a QLED, such as the comparative light-emitting element 100 illustrated in FIG. 14, the EML 14; namely, the QD layer, and the ETL 15 are formed of nanoparticles. Through gaps between the nanoparticles, impurities can enter inside the element.

For example, if ZnO-NPs have a diameter of 8 nm, the gaps between the ZnO-NPs are sized to allow transmission of particles having a diameter of 1.24 nm even if the ZnO-NPs are closely packed. Oxygen molecules have a diameter of 0. 296 nm and water molecules have a diameter of 0.38 nm. Hence, the gaps between the ZnO-NP transmit the oxygen molecules and the water molecules.

Hence, as illustrated in FIG. 14, water and oxygen in the air inevitably enter inside the EML 14 through the ETL15 during, for example, the manufacturing process of the light-emitting element 31, depending on the manufacturing conditions. Furthermore, during the manufacturing process of the light-emitting element 31, a process solvent such as, for example, water might permeate into the lower layer and enter the EML14, thereby causing the QDs 14a to be degraded. Moreover, a residual solvent such as, for example, water also spreads and moves into the EML 14 from such functional layers as the HIL 12 and the HTL 13 provided between the anode 11 and cathode 16 below the EML 14.

In addition, atoms of metals such as Ag and Al are also smaller than the above-described gaps between the ZnO-NPs, and the gaps transmit the atoms. Hence, when the cathode 16 is formed by such techniques as vapor deposition and sputtering, for example, metallic atoms from the cathode 16; that is, an electrode material, might enter either inside the ETL 15 or inside the EML 14 through the ETL 15. Furthermore, during driving, for example, cations from the anode 11, such as In and Sn of ITO, might diffuse and move to an upper layer, and enter inside the EML 14. Such movements of the electrode materials from the cathode 16 or the anode 11 causes a reaction between a functional layer and the electrode material in the light-emitting element 31, and a short circuit of the electrode.

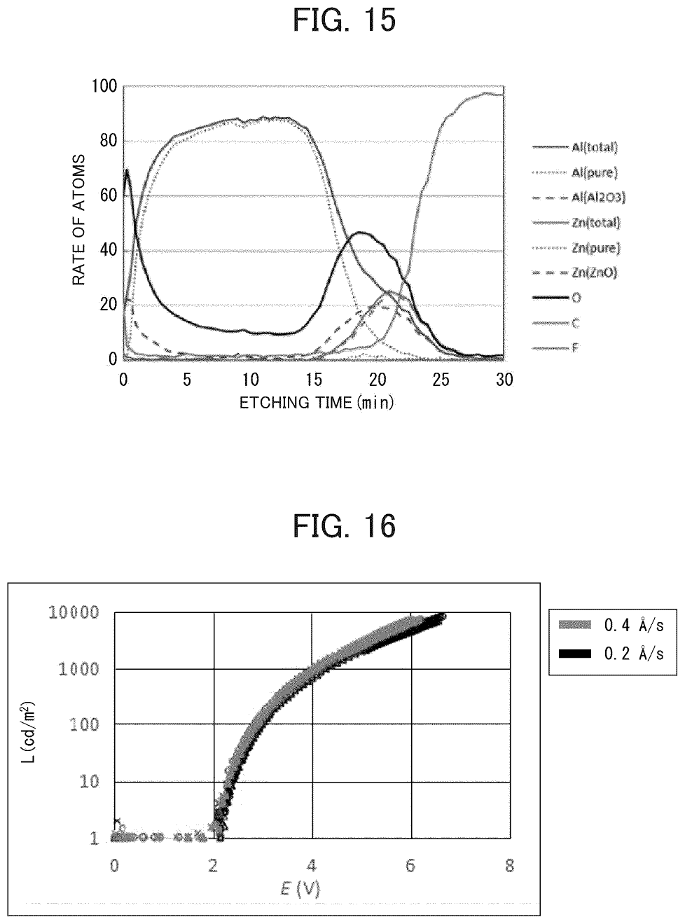

FIG. 15 is a graph showing a result of measuring, by the Auger electronic spectroscopy (AES), elements contained in the cathode 16, the ETL 15, and the EML 14 (the QD layer) of a light-emitting element. In the light-emitting element, a layer containing the first material 21 is not provided between the anode 11 and the cathode 16.

The light-emitting element used for the measurement was produced by the method below. First, on a glass substrate, an ITO film was formed as an anode to have a thickness of 30 nm. Next, on the ITO film, a CuSCN layer of 45 nm was formed to serve as an HIL. Next, on the CuSCN layer, a P-TPD layer of 40 nm was formed to serve as an HIL. Next, a dispersion liquid was formed of: QDs containing Cd and emitting a red light; and octane in which the QDs were dispersed. On the P-TPD layer, the dispersion liquid was applied and baked to form a QD layer having a thickness of 30 nm. Next, on the QD layer, a ZnO-NP layer having a thickness of 57 nm was formed to serve as an ETL. The ZnO-NP layer was formed of ZnO-NPs having a diameter of 12 nm. Next, on the ZnO-NP layer, Al having a thickness of 100 nm was formed as a cathode.

The measurement involved etching the light-emitting element with Ar ions from toward the cathode, and analyzing elements released by the etching to identify the elements contained in each of the layers. FIG. 15 shows a relationship between an etching time and a rate of each of the detected elements (atoms).

Note that, in FIG. 15, “Al (pure)” represents metallic Al, “Al (Al₂O₃)” represents Al in alumina, and “Al (total)” represents Al (pure) and Al (Al₂O₃) in total. Furthermore, “Zn (pure)” represents metallic Zn, “Zn(ZnO)” represents Zn in zinc oxide, and “Zn (total)” represents Zn (pure) and Zn (ZnO) in total. Moreover, “O”, “C”, and “F” represent the respective elements.

The result in FIG. 15 shows that Al is detected in large amount together with ZnO, and that Al serving as an electrode material enter the ZnO-NP layer and around the QD layer. The electrode material entering the ZnO-NP layer might cause a reaction of the QD layer and Al over time. In addition, if Al crystals such as dendrites are formed, the Al crystals are highly likely to cause current leakage or degradation of a lower layer such as the QD layer.

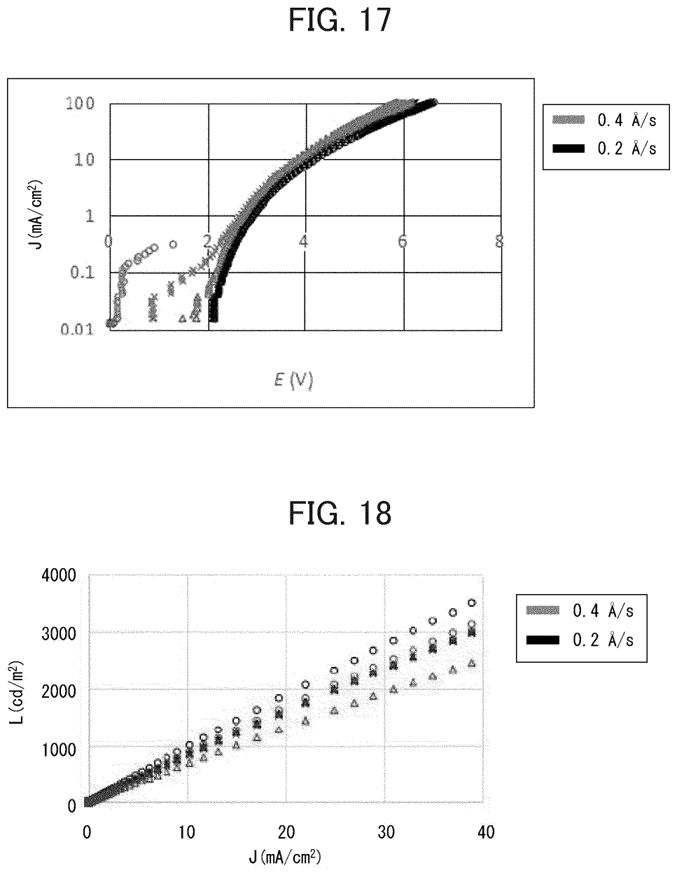

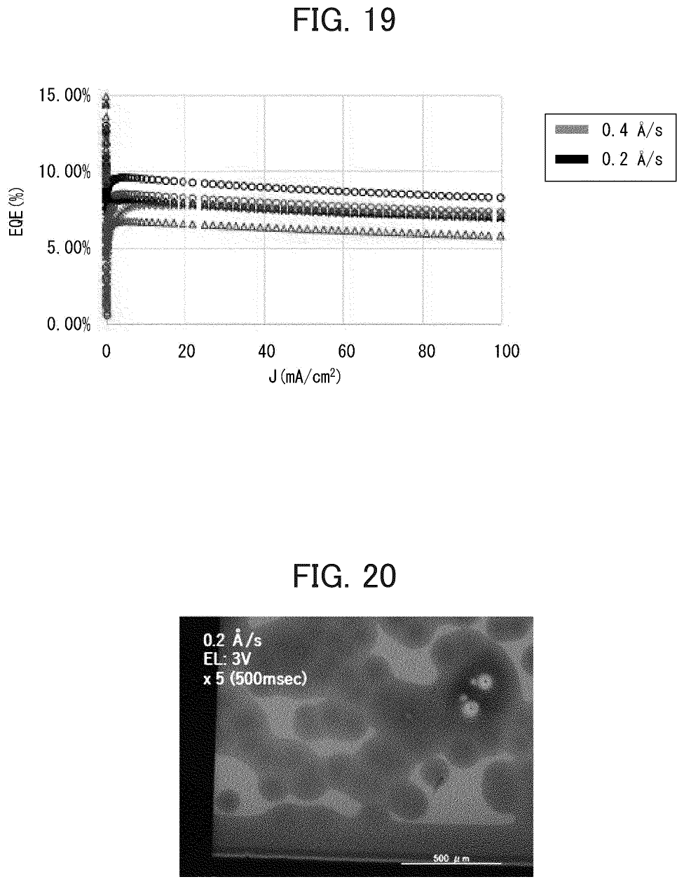

FIG. 16 is a graph illustrating a relationship between a vapor deposition rate, a drive voltage E (V), and a luminance L (cd/m²) when a light-emitting element is produced as a sample to have the same configuration as that of the light-emitting element used for the measurement in FIG. 15 except for the electrodes, while the vapor deposition rate of the cathode (Ag) is varied. FIG. 17 is a graph illustrating a relationship between a vapor deposition rate, a drive voltage E (V), and a current density J (mA/cm²) of a drive current when a light-emitting element is produced as a sample to have the same configuration as that of the light-emitting element used for the measurement in FIG. 15 except for the electrodes while the vapor deposition rate of Ag is varied. FIG. 18 is a graph illustrating a relationship between a vapor deposition rate, a current density J (mA/cm²) of a drive current, and a luminance L (cd/m²) when a light-emitting element is produced as a sample to have the same configuration as that of the light-emitting element used for the measurement in FIG. 15 except for the electrodes while the vapor deposition rate of Ag is varied. FIG. 19 is a graph illustrating a relationship between a vapor deposition rate, a current density J (mA/cm²) of a drive current, and an external quantum efficiency EQE (%) when a light-emitting element is produced as a sample to have the same configuration as that of the light-emitting element used for the measurement in FIG. 15 except for the electrodes while the vapor deposition rate of Ag is varied. FIGS. 16 to 18 illustrate graphs observed when Ag is formed multiple times to measure up to 25 nm at vapor deposition rates of 0.2 Å/s and 0.4 Å/s. Like reference signs designate the same samples.

Note that the luminance L was measured with a company LED luminance measuring device. The EQE is calculated from the measured luminance L, the injected current, and the emission spectrum.

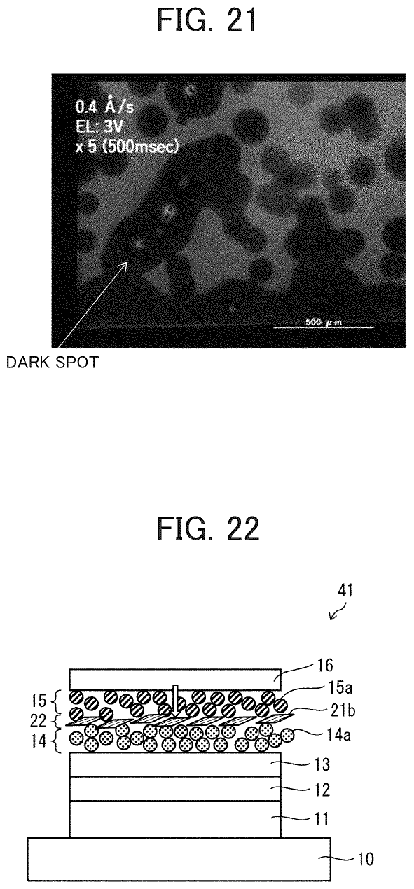

Furthermore, FIG. 20 is an image showing the light-emitting element emitting light by electroluminescence when the light-emitting element is manufactured to have the same configuration as that of the light-emitting element used for the measurement in FIG. 15 except for the electrode, while Ag has a vapor deposition rate of 0.2 Å/s. Furthermore, FIG. 21 is an image showing the light-emitting element emitting light by electroluminescence when the light-emitting element is manufactured to have the same configuration as that of the light-emitting element used for the measurement in FIG. 15 except for the electrode, while Ag has a vapor deposition rate of 0.4 Å/s. Note that these images of light emitted by EL are obtained with an epi-illumination microscope manufactured by Olympus Marketing Inc.

For example, the result seen in FIG. 17 shows that, if the vapor deposition rate of Ag rises, the fluctuation of the J-V (the current-voltage) curve increases at a low voltage; that is, a current leakage increases. Moreover, the results seen in FIGS. 20 and 21 show that, if the vapor deposition rate of Ag rises, the dark spots appear noticeably.

The noticeable dark spots indicate that, when the vapor deposition rate of Ag is high (i.e., when Ag is vapor-deposited with a heating temperature of a vapor deposition source set higher), the energy (i.e., kinetic energy of atoms) of Ag atoms at the time of the vapor deposition increases accordingly, and more Ag penetrates into the ZnO-NPs, and a current path is formed by Ag penetrating into the ZnO-NP layer and, further, into the QD layer. Such a current leakage path decreases light emission efficiency. In addition, the current leakage path makes the current flow uneven; that is, the current is likely to flow locally. The uneven current flow is a cause of a decrease in reliability.

As described before, the h-BN nanosheets 21b have a high barrier property, against impurities, in the direction perpendicular to the film surface. This high barrier property can prevent the impurities from penetrating into the element as shown in FIG. 14. Such a feature can reduce degradation of the QDs 14a and, in view of long-time reliability, the amount of water and oxygen inside the device. In addition, when mixed into the functional layers; particularly, when mixed into the HTL 13 and the ETL 15, the h-BN nanosheets 21b oriented in the film surface direction are effective for prevention of the above-described penetration of the metallic atoms when an electrode is formed.

Furthermore, a light-emitting element referred to as a QLED is very thin as a whole; that is, for example, approximately 100 to 200 nm. Even a voltage of several volts produces very high electric field strength. For example, a voltage of 5V produces an electric field strength of 50 MV/m. Thus, in particular, impurity ions found inside the light-emitting element easily move during long-time driving and unintentionally react with each of the materials inside the light-emitting element. As a result, the light-emitting element is inevitably degraded.

Hence, as described above, the h-BN nanosheets 21b oriented in the film surface direction are provided between the anode 11 and the cathode 16, thereby successfully reducing a significant amount of impurities crossing the layer containing the h-BN nanosheets 21b. Such a feature can reduce an unintended chemical reaction, and further improve reliability of the light-emitting element 31. As can be seen, the h-BN nanosheets 21b oriented in the film surface direction are provided between the anode 11 and the cathode 16, thereby successfully keeping the above-described impurities from moving after the light-emitting element 31 is produced.

### Third Embodiment

The first and second embodiments exemplify a case where the first material 21 is mixed into at least one of the functional layers provided between the anode 11 and the cathode 16, so that at least one layer containing the first material 21 is provided between the anode 11 and the cathode 16. However, as described before, the functional layers may include at least one first material layer formed of the first material 21.

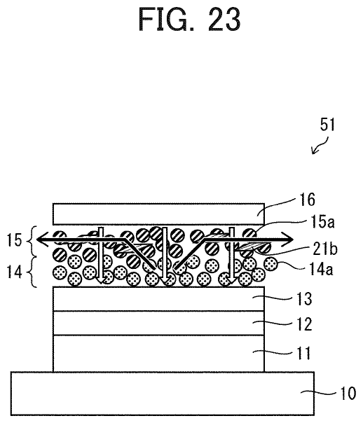

FIG. 22 is a cross-sectional view schematically illustrating an example of a light-emitting element 41 according to this embodiment. Furthermore, FIG. 23 is a cross-sectional view schematically illustrating an example of a light-emitting element 51 according to this embodiment.

The light-emitting element 41 and the light-emitting element 51 are the same in configuration as the light-emitting element described in either the first embodiment or the second embodiment except for the points to be described below.

The light-emitting element 41 illustrated in FIG. 22 includes, for example, a first material layer 22 formed of the first material 21 and provided between the EML 14 and the ETL15.

Note that FIG. 22 exemplifies a case where the first material 21 is the h-BN nanosheets 21b. However, this embodiment shall not be limited to such a case. The first material layer 22 may include the c-BN nanoparticles 21a instead of, or in addition to, the h-BN nanosheets 21b. Furthermore, the first material layer 22 may be formed in any given position as long as the first material layer 22 is positioned between the anode 11 and the cathode 16. Moreover, the first material layer 22 may be provided between, for example, the anode 11 and the cathode 16 to sandwich one of, or two or more of, the HIL 12, the HTL 13, the EML 14, and the ETL 15. The first material layer 22 may include a plurality of the first material layers 22 provided between the anode 11 and the cathode 16. For example, one such first material layer 22 may be formed between the layers; namely, the anode 11, the HIL 12, the HTL 13, the EML 14, the ETL 15, and the cathode 16. The first material layers 22 may be provided in any given numbers.

As can be seen, the layer containing the first material 21 may be formed as a single layer containing the first material 21 alone. In any case, at least one layer containing the first material 21 is provided between the anode 11 and the cathode 16. Such a feature can achieve the same advantageous effects as those described in the first and second embodiments.

Note that, as described before, BN is an insulator, and if the first material layer 22 has a thickness of more than 2 nm, a tunneling current might not flow in the direction perpendicular to the film surface direction (i.e., in the film thickness direction). As a result, the voltage might rise (the resistance might rise) and the light-emitting element might become unusable. Hence, the first material layer 22 has a thickness of desirably 2 nm or less.

Thus, when the first material layer 22 is provided to serve as a functional layer, it is more desirable that the first material layer 22 having a thickness of 2 nm or less is formed to sandwich a functional layer other than the first material layer 22, in order to enhance an advantageous effect of improving thermal conductivity.

Whereas, the light-emitting element 51 illustrated in FIG. 23 includes, for example, the ETL 15 into which, for example, the h-BN nanosheets 21b are mixed as the first material 21. In this case, the h-BN nanosheets 21b each having a film thickness of 2 nm or less are dispersed in, for example, the ETL 15. Thus, the tunnelling current can flow on the h-BN nanosheets 21b. As a result, the h-BN nanosheets 21b do not become a large resistance, and can be mixed into the ETL at a high volume rate. Such a feature can readily ensure sufficient thermal conductivity in the film surface direction.

### Fourth Embodiment

As described before, a light-emitting element according to an aspect of the present disclosure may be used as, for example, a light source of a light-emitting device such as a display device or a lighting device.

A light-emitting device according to an aspect of the present disclosure may include at least one light-emitting element according to an aspect of the present disclosure. Described below as an example will be a display device including a plurality of light-emitting elements according to an aspect of the present disclosure, as a light-emitting device according to an aspect of the present disclosure. However, this embodiment shall not be limited to such an example.

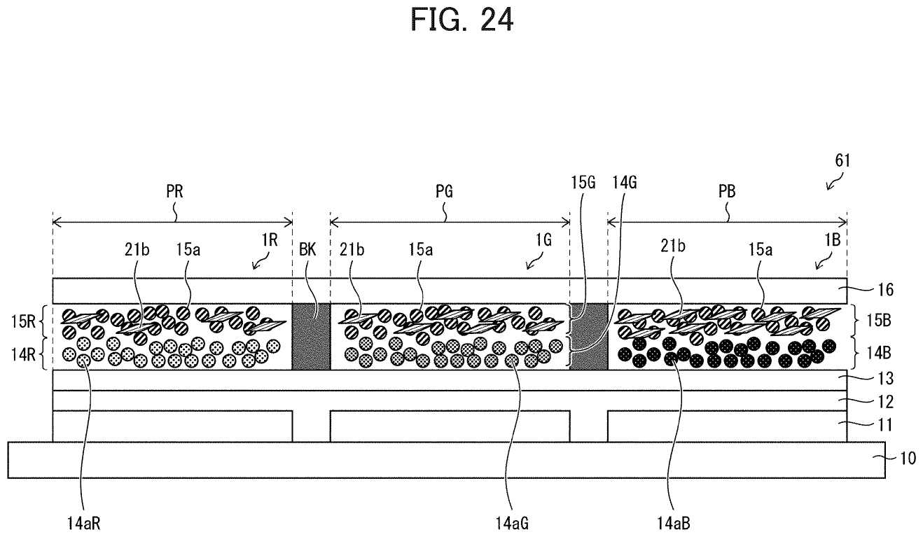

FIG. 24 is a cross-sectional view illustrating an example of a schematic configuration of a main feature of a display device 61 (i.e., a light-emitting device) according to this embodiment.

The display device 61 has a plurality of pixels. Each of the pixels is provided with a light-emitting element. Between the pixels, a bank BK is provided to serve as a pixel separating film to separate the neighboring pixels from one another. The bank BK is insulative. The display device 61 includes, as the substrate 10, an array substrate in which a drive element layer is formed. The display device 61 further includes a light-emitting element layer stacked on the substrate 10 and including: a plurality of the light-emitting elements having different emission wavelengths; and the bank BK.

The light-emitting element layer includes the plurality of light-emitting elements provided for the respective pixels. Above the substrate 10, the layers of each of the light-emitting elements are stacked on top of another. Here, the substrate 10 is, for example, a TFT substrate (an array substrate) including: an insulating substrate; and a TFT layer including a plurality of TFTs provided on the insulating substrate, and serving as a drive element layer.

The display device 61 illustrated in FIG. 24 includes, as pixels: a red pixel PR that emits a red light; a green pixel PG that emits a green light; and a blue pixel PB that emits a blue light.

The red pixel PR is provided with a red light-emitting element serving as a light-emitting element to emit a red light. The green pixel PG is provided with a green light-emitting element serving as a light-emitting element. The blue pixel PB is provided with a blue light-emitting element serving as a light-emitting element.

As seen in the first to third embodiments, exemplified below will be a case where each of the light-emitting elements above has a conventional structure in which the anode 11 is a lower electrode and the cathode 16 is an upper electrode. However, in this embodiment, the light-emitting element may also have an inverted structure in which the cathode is a lower electrode and the anode is an upper electrode.

The red light-emitting element may include: the anode 11; the HIL 12; the HTL 13; the EML 14R; the ETL 15R; and the cathode 16, all of which are stacked on top of another in the stated order above the substrate 10. The green light-emitting element may include: the anode 11; the HIL 12; the HTL 13; the EML 14G; the ETL 15G; and the cathode 16, all of which are stacked on top of another in the stated order above the substrate 10. The blue light-emitting element may include: the anode 11; the HIL 12; the HTL 13; the EML 14B; the ETL 15B; and the cathode 16, all of which are stacked on top of another in the stated order above the substrate 10.

The EML 14R, a red EML that emits a red light, contains red QDs 14aR serving as the QDs 14a to emit the red light. The EML 14G, a green EML that emits a green light, contains green QDs 14aG serving as the QDs 14a to emit the green light. The EML 14B, a blue EML that emits a blue light, contains blue QDs 14aB serving as the QDs 14a to emit the blue light. Note that the same light-emitting elements (the same pixels) include the same kind of QDs 14a.

Each of the anodes 11, which functions as a so-called pixel electrode (i.e., an island-shaped lower electrode), is shaped into an island and provided on the substrate 10 for a corresponding one of the light-emitting elements (i.e., for a corresponding one of the pixels). Whereas, the cathode 16, which functions as a common electrode, is provided in common to all the light-emitting elements (i.e., to all the pixels). The light-emitting elements function as light sources to cause the respective pixels to glow.

The EML 14R, the EML 14G, and the EML 14B are colored separately for the respective pixels, and are separated into islands by the bank BK. Likewise, the ETL 15R, the ETL 15G, and the ETL 15B are colored separately for the respective pixels, and are separated into islands by the bank BK. In forming the bank BK, for example, an organic material such as polyimide or acrylic resin is applied. After that, the applied organic material is patterned by photolithography to form the bank BK.

FIG. 24 exemplifies a case where the h-BN nanosheets 21b are mixed into the ETL 15R, the ETL 15G, and the ETL 15B alone, and serve as the first material 21.

The display device 61 illustrated in FIG. 24 includes the plurality of light-emitting elements as described above. A light-emitting element that emits light in a wavelength band with a shorter peak emission wavelength contains the first material 21 in larger amount in a cross-sectional area ratio with respect to a layer containing the first material 21.

As to the EML 14R, the EML 14G, and the EML 14B, an EML that emits light in a wavelength band with a shorter peak emission wavelength exhibits a larger Eg of the QDs 14a. Hence, an EML that emits light in a wavelength band with a shorter peak emission wavelength exhibits a higher light-emission threshold voltage and generates a larger amount of heat.

The light-emission threshold voltage indicates a voltage applied to a light-emitting element and increased so that the light-emitting element starts to emit light. When the light-emitting element is optimized in structure, and thus is ideal, the light-emission threshold value represents a value of the Eg of the QDs 14a converted into a voltage value.

The Eg holds a relationship representing: the Eg of the QDs 14aR <the Eg of the QDs 14aG <the Eg of the QDs 14aB. Hence, in this case, as illustrated in FIG. 15, the content of the first material 21 in the cross-sectional area ratio with respect to the layers included in the light-emitting elements and containing the first material 21 increases in the order of the red light-emitting element <the green light-emitting element <the blue light-emitting element.

Note that FIG. 24 exemplifies a case where the layer containing the first material is the ETL 15. Alternatively, the layer containing the first material 21 may be a layer other than the ETL 15.

As can be seen, a content of the first material 21 in a cross-sectional area ratio with respect to a layer containing the first material 21 is set larger as the Eg of the QDs 14a is larger. Such a feature makes it possible for a light-emitting element driven on a larger voltage to sufficiently diffuse higher Joule heat and sufficiently reduce locally accumulated heat.

Note that this embodiment exemplifies a case where the light-emitting device is a full-color display device. However, this embodiment shall not be limited to such a case. The above technique can be applied to all the light-emitting devices having a plurality of light-emitting elements with different peak emission wavelengths.

That is, in a light-emitting device having a plurality of light-emitting elements including: a first light-emitting element that emits light in a first wavelength band; and a second light-emitting element that emits light in a second wavelength band a peak emission wavelength of which is shorter than a peak emission wavelength of the first light-emitting element, a content of the first material 21 in a cross-sectional area ratio with respect to a layer included in the second light-emitting element and containing the first material 21 may be larger than a content of the first material in a cross-sectional area ratio with respect to a layer included in the first light-emitting element and containing the first material 21. Such a feature makes it possible to achieve the above advantageous effects.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. (canceled)

2. A light-emitting element, comprising:
a first electrode;
a second electrode; and
at least one layer provided between the first electrode and the second electrode,
wherein the at least one layer includes a first material that contains c-BN nanoparticles.

3. The light-emitting element according to claim 2,
wherein the first material further contains h-BN nanosheets.

4. A light-emitting element, comprising:
a first electrode and a second electrode;
at least one layer provided between the first electrode and the second electrode, and containing a first material containing h-BN nanosheets; and
a plurality of functional layers between the first electrode and the second electrode,
wherein all of the plurality of functional layers contain the first material.

5. The light-emitting element according to claim 2, further comprising:
a light-emitting layer provided between the first electrode and the second electrode,
wherein the light-emitting layer contains quantum dots and the first material.

6. The light-emitting element according to claim 2, further comprising:
at least a light-emitting layer provided between the first electrode and the second electrode, and containing quantum dots; and
a charge transport layer provided at least one of:
between the first electrode and the light-emitting layer or between the second electrode and
wherein at least one of the charge transport layer or the light-emitting layer contains the first material.

7. The light-emitting element according to claim 2, further comprising:
a plurality of functional layers between the first electrode and the second electrode,
wherein all of the plurality of functional layers contain the first material.

8. The light-emitting element according to claim 2,
wherein a content of the first material in the at least one layer is 25% or higher and 80% or lower in a cross-sectional area ratio with respect to the at least one layer.

9. The light-emitting element according to claim 4,
wherein an average thickness of the h-BN nanosheets is 2 nm or less per unit area of a cross-section, of the at least one layer, in a thickness direction.

10. The light-emitting element according to claim 9,
wherein an average value of an angle formed between each of the h-BN nanosheets and a plane parallel with a film surface of a layer containing the first material is smaller than 45 degrees per unit area of a cross-section, of the at least one layer, in the thickness direction.

11. The light-emitting element according to claim 10,
wherein the h-BN nanosheets have a size of 50 nm×50 nm or more in an intra-film direction of the h-BN nanosheets.

12. The light-emitting element according to claim 4,
wherein the h-BN nanosheets have a size of 100 nm×100 nm or more in an intra-film direction of the h-BN nanosheets.

13. A light-emitting device comprising: at least one light-emitting element according to claim 2.

14. A light-emitting device comprising:
at least two light-emitting elements according to claim 2, wherein
the at least two light-emitting elements include a first light-emitting element and a second light-emitting element,
an emission wavelength of the second light-emitting element is shorter than an emission wavelength of the first light-emitting element, and
a content of the first material in the at least one layer of the second light-emitting element is larger than a content of the first material in the at least one layer of the first light-emitting element, with respect to a cross-sectional area ratio.

15. (canceled)

16. (canceled)

17. The light-emitting element according to claim 4,
wherein a content of the first material in any layer containing the first material is 25% or higher and 80% or lower in a cross-sectional area ratio with respect to the layer.

18. A light-emitting device comprising:
at least two light-emitting elements,
wherein each of the at least two light-emitting elements includes:
a first electrode and a second electrode;
at least one layer provided between the first electrode and the second electrode, and containing a first material containing h-BN nanosheets;
a first light-emitting element; and
a second light-emitting element,
an emission wavelength of the second light-emitting element is shorter than an emission wavelength of the first light-emitting element, and
a content of the first material in the at least one layer of the second light-emitting element is larger than a content of the first material in the at least one layer of the first light-emitting element, with respect to a cross-sectional area ratio.

19. A light-emitting device according to claim 18,
wherein each of the at least two light-emitting elements further comprises:
a plurality of functional layers between the first electrode and the second electrode,
wherein all of the plurality of functional layers contain the first material.
